(19) United States
(12) Patent Application Publication
(10) Pub. No.: US 2024/0170525 A1
(43) Pub. Date: May 23, 2024

(54) SENSOR DEVICE

(71) Applicant: SONY SEMICONDUCTOR SOLUTIONS CORPORATION, Kanagawa (JP)

(72) Inventors: Hidenobu TSUGAWA, Kanagawa (JP); Ryoko KAJIKAWA, Kanagawa (JP)

(73) Assignee: SONY SEMICONDUCTOR SOLUTIONS CORPORATION, Kanagawa (JP)

(21) Appl. No.: 18/551,254

(22) PCT Filed: Mar. 22, 2022
(86) PCT No.: PCT/JP2022/012946

§ 371 Date: Sep. 19, 2023

(30) Foreign Application Priority Data
Mar. 31, 2021 (JP) 2021-061853

(51) Int. Cl. H01L 27/146; H01L 31/107

(52) U.S. Cl. CPC H01L 27/14634; H01L 27/14623; H01L 27/1463; H01L 27/14636; H01L 27/14645; H01L 27/1465; H01L 31/107

(57) ABSTRACT

Provided is a sensor device capable of miniaturizing an SPAD pixel. The sensor device includes a first substrate unit and a second substrate unit bonded to the first substrate unit. The first substrate unit includes a first semiconductor substrate and a pixel region provided on the first semiconductor substrate and in which the SPAD pixel and a plurality of visible-light pixels are mixed in an array. The second substrate unit includes a second semiconductor substrate facing the first semiconductor substrate, an SPAD circuit provided on the second semiconductor substrate and connected to the SPAD pixel, and a visible-light pixel circuit provided on the second semiconductor substrate and connected to the plurality of visible-light pixels.

### TECHNICAL FIELD

The present disclosure relates to a sensor device.

### BACKGROUND ART

In general, in a case where image information captured by an image sensor and distance information measured by a distance sensor are combined to provide an image with three-dimensional data, the image sensor and the distance sensor create and dispose respective chips thereof with separate camera modules, and match information of the image and information of the distance in data processing in a subsequent circuit. In this case, a plurality of camera modules is required, and costs increase. Furthermore, mounting areas of modules are increased, and because each module has a different optical axis, parallax increases at a short distance, and data processing in consideration of it is required.

In order to solve the problem, a stacked sensor in which a chip and a logic circuit are stacked has been proposed (refer to Patent Document 1, for example), the chip including single photon avaranche diode (SPAD) pixels arranged in an array (hereinafter, referred to as an SPAD array).

### CITATION LIST

### Patent Document

Patent Document 1: Japanese Patent Application Laid-Open No. 2019-47486

### SUMMARY OF THE INVENTION

### Problems to be Solved by the Invention

An SPAD circuit disposed, corresponding to each of a plurality of SPAD pixels, under the SPAD array in which a plurality of SPAD pixels is disposed in an array has such a problem that it is difficult to miniaturize the SPAD pixels because a size thereof is limited to a size of the SPAD circuit.

The present disclosure has been made in view of such circumstances, and an object thereof is to provide a sensor device capable of miniaturizing an SPAD pixel.

### Solutions to Problems

A sensor device according to one aspect of the present disclosure includes a first substrate unit and a second substrate unit bonded to the first substrate unit. The first substrate unit includes a first semiconductor substrate and a pixel region provided on the first semiconductor substrate and in which an SPAD pixel and a plurality of visible-light pixels are mixed in an array. The second substrate unit includes a second semiconductor substrate facing the first semiconductor substrate, an SPAD circuit provided on the second semiconductor substrate and connected to the SPAD pixel, and a visible-light pixel circuit provided on the second semiconductor substrate and connected to the plurality of visible-light pixels.

With this arrangement, the sensor device can use the plurality of visible-light pixels as pixels for imaging (that is, for picture image acquisition) and the SPAD pixel as a pixel for distance measurement (that is, for distance image acquisition). In the first semiconductor substrate, the SPAD pixel and the plurality of visible-light pixels are disposed in an array in a mixed manner, and therefore the sensor device can acquire a picture image and a distance image on the same optical axis.

Furthermore, in the first semiconductor substrate, if the SPAD pixel is reduced in size in plan view (that is, miniaturized), a free region is generated around the SPAD pixel by an amount of the miniaturization. In the sensor device, the SPAD pixel and the plurality of visible-light pixels are disposed in an array in a mixed manner, and therefore the visible-light pixels can be disposed in the free region generated by the miniaturization of the SPAD pixel. As a result, the SPAD pixel can be miniaturized without the size thereof being limited to the size of the SPAD circuit.

### BRIEF DESCRIPTION OF DRAWINGS

FIG. 1 is a block diagram illustrating a configuration example of a sensor device according to a first embodiment of the present disclosure.

FIG. 2 is a block diagram illustrating a configuration example of an imaging unit according to the first embodiment of the present disclosure.

FIG. 3 is a block diagram illustrating a configuration example of a distance measurement unit according to the first embodiment of the present disclosure.

FIG. 4A is a plan view illustrating a first configuration example of a first substrate unit according to the first embodiment of the present disclosure.

FIG. 4B is a plan view illustrating a first configuration example of a second substrate unit according to the first embodiment of the present disclosure.

FIG. 5A is a plan view illustrating a second configuration example of the first substrate unit according to the first embodiment of the present disclosure.

FIG. 5B is a plan view illustrating a second configuration example of the second substrate unit according to the first embodiment of the present disclosure.

FIG. 6 is a diagram illustrating a configuration example of an SPAD circuit positioned immediately below a pixel region.

FIG. 7 is a diagram illustrating an SPAD pixel, a connection example of an AFE circuit and a TDC circuit, and a configuration example of the AFE circuit.

FIG. 8 is a flowchart illustrating each operation example of an SPAD circuit and CIS circuit in the sensor device.

FIG. 9 is a cross-sectional view illustrating a configuration example of the sensor device according to the first embodiment of the present disclosure.

FIG. 10 is a cross-sectional view illustrating a configuration example of an SPAD pixel according to the first embodiment of the present disclosure.

FIG. 11 is a plan view illustrating a size example (first example) of the SPAD pixel and SPAD circuit according to the first embodiment of the present disclosure.

FIG. 12 is a plan view illustrating a size example (second example) of the SPAD pixel and SPAD circuit according to the first embodiment of the present disclosure.

FIG. 13 is a plan view illustrating a size example (third example) of the SPAD pixels and SPAD circuit according to the first embodiment of the present disclosure.

FIG. 14 is a plan view illustrating a size example (fourth example) of the SPAD pixel and SPAD circuit according to the first embodiment of the present disclosure.

FIG. 15A is a plan view illustrating a configuration example (Modification 1) of the first substrate unit according to the first embodiment of the present disclosure.

FIG. 15B is a plan view illustrating a configuration example (Modification 1) of the second substrate unit according to the first embodiment of the present disclosure.

FIG. 16 is a cross-sectional view illustrating a configuration example (Modification 2) of the sensor device according to the first embodiment of the present disclosure.

FIG. 17 is a cross-sectional view illustrating a configuration example (Modification 3) of the sensor device according to the first embodiment of the present disclosure.

FIG. 18 is a cross-sectional view illustrating a configuration example (Modification 4) of the first substrate unit according to the first embodiment of the present disclosure.

FIG. 19A is a plan view illustrating a configuration example (Modification 4) of a back surface side of the first semiconductor substrate.

FIG. 19B is a plan view illustrating a configuration example (Modification 4) of a front surface side of the first semiconductor substrate.

FIG. 20 is a cross-sectional view illustrating a configuration example (Modification 5) of the first substrate unit according to the first embodiment of the present disclosure.

FIG. 21 is a cross-sectional view illustrating a configuration example (Modification 6) of the first substrate unit according to the first embodiment of the present disclosure.

FIG. 22 is a cross-sectional view illustrating a configuration example (Modification 7) of the first substrate unit according to the first embodiment of the present disclosure.

FIG. 23 is a cross-sectional view illustrating a configuration example (Modification 7) of the first substrate unit according to the first embodiment of the present disclosure.

FIG. 24A is a cross-sectional view illustrating a method for manufacturing a sensor device according to a second embodiment of the present disclosure in order of process.

FIG. 24B is a cross-sectional view illustrating a method for manufacturing the sensor device according to the second embodiment of the present disclosure in order of process.

FIG. 24C is a cross-sectional view illustrating a method for manufacturing the sensor device according to the second embodiment of the present disclosure in order of process.

FIG. 24D is a cross-sectional view illustrating a method for manufacturing the sensor device according to the second embodiment of the present disclosure in order of process.

FIG. 24E is a cross-sectional view illustrating a method for manufacturing the sensor device according to the second embodiment of the present disclosure in order of process.

FIG. 24F is a cross-sectional view illustrating a method for manufacturing the sensor device according to the second embodiment of the present disclosure in order of process.

FIG. 25 is a cross-sectional view illustrating a configuration example of a sensor device according to a third embodiment of the present disclosure.

FIG. 26A is a circuit diagram illustrating an arrangement example of a CIS pixel according to the third embodiment of the present disclosure.

FIG. 26B is a circuit diagram illustrating an arrangement example of the CIS pixel according to the third embodiment of the present disclosure.

FIG. 27 is a circuit diagram illustrating an arrangement example (Modification 1) of an SPAD pixel and SPAD circuit according to the third embodiment of the present disclosure.

FIG. 28 is a circuit diagram illustrating an arrangement example (Modification 2) of an SPAD pixel and SPAD circuit according to the third embodiment of the present disclosure.

### MODE FOR CARRYING OUT THE INVENTION

Hereinafter, embodiments of the present disclosure will be described with reference to the drawings. In the description of the drawings referred to in the following description, the same or similar parts are denoted by the same or similar reference signs. It should be noted that the drawings are schematic, and a relationship between a thickness and a planar dimension, a ratio of the thicknesses between layers and the like are different from actual ones. Therefore, specific thicknesses and dimensions should be determined in consideration of the following description. Furthermore, it goes without saying that dimensional relationships and ratios are partly different between the drawings.

Definition of directions such as upward and downward directions in the following description is merely the definition for convenience of description, and does not limit the technical idea of the present disclosure. For example, it goes without saying that if a target is observed while being rotated by 90°, the upward and downward directions are converted into rightward and leftward directions, and if the target is observed while being rotated by 180°, the upward and downward directions are inverted.

In the following description, the direction is sometimes described using terms such as an X-axis direction, a Y-axis direction, and a Z-axis direction. The X-axis direction and the Y-axis direction are an example of a “first direction” in the present disclosure and an example of a “second direction” in the present disclosure, respectively, and are directions parallel to a back surface (light-receiving surface) 5a of a first semiconductor substrate 5. The X-axis direction and the Y-axis direction may be referred to as horizontal directions. The Z-axis direction is a direction perpendicular to the back surface 5a of the first semiconductor substrate 5. The Z-axis direction is also a thickness direction of a sensor device 100. The X-axis direction, the Y-axis direction, and the Z-axis direction are orthogonal to each other.

### FIRST EMBODIMENT

### (Configuration Example of Sensor Device)

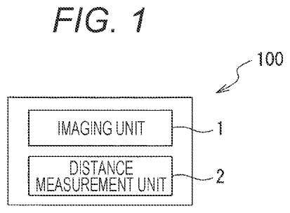

FIG. 1 is a block diagram illustrating a configuration example of a sensor device 100 according to a first embodiment of the present disclosure. As illustrated in FIG. 1, the sensor device 100 according to the first embodiment of the present disclosure is a device including an imaging unit 1 and a distance measurement unit 2, in which a plurality of CIS pixels 20 (CMOS image sensor: CIS, an example of “visible-light pixel” in the present disclosure) included in the imaging unit 1 and one or more SPAD pixels 10 included in the distance measurement unit 2 are disposed in a same pixel region 51. For example, a plurality of CIS pixels and one or more SPAD pixels 10 are disposed in the same pixel region 51 in an array in a mixed manner. Next, configuration examples of the imaging unit 1 and distance measurement unit 2 will be described.

### (Configuration Example of Imaging Unit)

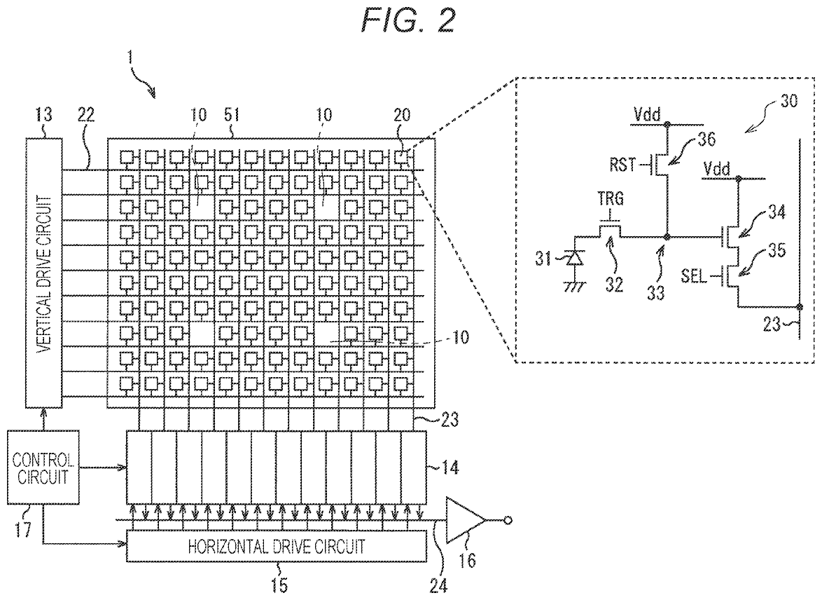

FIG. 2 is a block diagram illustrating a configuration example of the imaging unit 1 according to the first embodiment of the present disclosure. As illustrated in FIG. 2, the imaging unit 1 includes a plurality of CIS pixels 20 provided in the pixel region 51, a vertical drive circuit 13, a column signal processing circuit 14, a horizontal drive circuit 15, an output circuit 16, and a control circuit 17. The CIS pixels 20 detects visible light.

The CIS pixels 20 are light-receiving regions that receive visible light condensed by an optical system (not illustrated). The plurality of CIS pixels 20 is disposed in a matrix. The plurality of CIS pixels 20 is connected to the vertical drive circuit 13 for each row via the horizontal signal lines 22, and is connected to the column signal processing circuit 14 for each column via vertical signal lines 23. Each of the plurality of CIS pixels 20 outputs a pixel signal at a level corresponding to an amount of each ray of visible light received. An image of a subject is constructed from each of the pixel signals.

Via the horizontal signal lines 22, for each row of the plurality of CIS pixels 20, the vertical drive circuit 13 sequentially supplies drive signals for driving (transferring, selecting, resetting, or the like) each CIS pixel 20 to the CIS pixels 20. The column signal processing circuit 14 performs correlated double sampling (CDS) processing on the pixel signals output from the plurality of CIS pixels 20 via the vertical signal lines 23, thereby performing AD conversion on the pixel signals and removing reset noise.

For each column of the plurality of CIS pixels 20, the horizontal drive circuit 15 sequentially supplies the column signal processing circuit 14 with drive signals for causing the column signal processing circuit 14 to output the pixel signals to a data output signal line 24. The output circuit 16 amplifies the pixel signals supplied from the column signal processing circuit 14 via the data output signal line 24 at a timing according to the drive signals of the horizontal drive circuit 15, and outputs the amplified pixel signals to a signal processing circuit of a subsequent stage. The control circuit 17 controls driving of each block inside the imaging unit 1. For example, the control circuit 17 generates clock signals according to a drive cycle of the respective block and supplies the clock signals to each of the blocks.

The CIS pixels 20 include a PN photodiode 31 that photoelectrically converts visible light, a transfer transistor 32, a floating diffusion 33, an amplification transistor 34, a selection transistor 35, and a reset transistor 36. The transfer transistor 32, the floating diffusion 33, the amplification transistor 34, the selection transistor 35, and the reset transistor 36 constitute a reading circuit 30 that reads charge (pixel signal) photoelectrically converted by the PN photodiode 31.

The PN photodiode 31 is a photoelectric conversion unit that converts incident visible light into charge with photoelectric conversion and stores the charge, and has an anode terminal grounded and a cathode terminal connected to the transfer transistor 32. The transfer transistor 32 is driven in accordance with a transfer signal TRG supplied from the vertical drive circuit 13, and when the transfer transistor 32 is turned on, the charge stored in the PN photodiode 31 is transferred to the floating diffusion 33. The floating diffusion 33 is a floating diffusion region connected to a gate electrode of the amplification transistor 34 and having a predetermined storage capacitance, and the floating diffusion 33 temporarily stores the charge transferred from the PN photodiode 31.

The amplification transistor 34 outputs a pixel signal at a level (that is, a potential of the floating diffusion 33) corresponding to the charge stored in the floating diffusion 33 to a vertical signal line 23 via the selection transistor 35. That is, with a configuration in which the floating diffusion 33 is connected to the gate electrode of the amplification transistor 34, the floating diffusion 33 and the amplification transistor 34 function as a conversion unit that amplifies the charge generated in the PN photodiode 31 and converts the charge into a pixel signal at a level corresponding to the charge.

The selection transistor 35 is driven in accordance with a selection signal SEL supplied from the vertical drive circuit 13, and when the selection transistor 35 is turned on, the pixel signal output from the amplification transistor 34 can be output to a vertical signal line 23. The reset transistor 36 is driven in accordance with a reset signal RST supplied from the vertical drive circuit 13, and when the reset transistor 36 is turned on, the charge stored in the floating diffusion 33 is discharged to a drain power supply Vdd, and the floating diffusion 33 is reset.

In the pixel region 51 illustrated in FIG. 2, regions indicated by blanks space are mixed in the CIS pixels 20 arranged in an array. For example, the SPAD pixels 10 are disposed in the regions indicated by the blanks.

### (Configuration Example of Distance Measurement Unit)

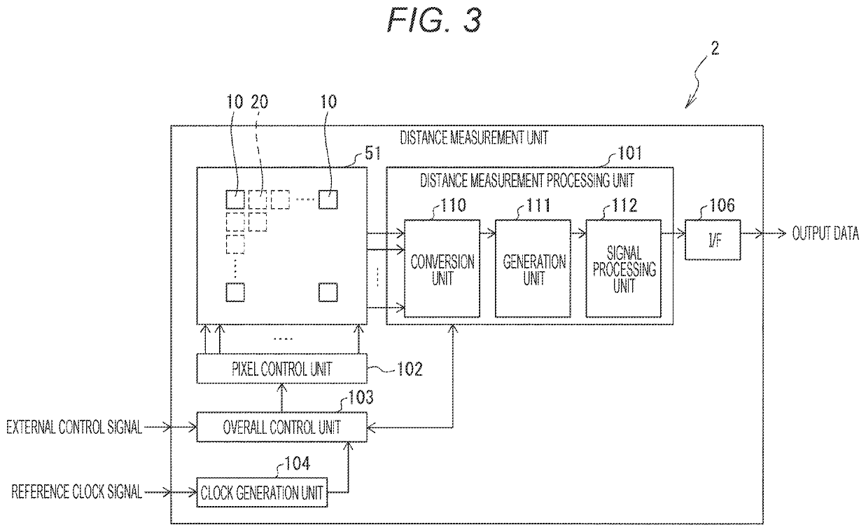

FIG. 3 is a block diagram illustrating a configuration example of a distance measurement unit 2 according to the first embodiment of the present disclosure. The distance measurement unit 2 is a device that directly performs distance measurement with, for example, time of flight (ToF), and is a device that calculates a distance on the basis of a time during which light emitted from an external light source (not illustrated) is reflected and returned. As illustrated in FIG. 3, the distance measurement unit 2 includes one or more SPAD pixels 10 disposed in the pixel region 51, a distance measurement processing unit 101, a pixel control unit 102, an overall control unit 103, a clock generation unit 104, and an interface (I/F) 106. The SPAD pixel 10 detects, for example, infrared light as monitor light. The SPAD pixels 10, the distance measurement processing unit 101, the pixel control unit 102, the overall control unit 103, the clock generation unit 104, and the I/F 106 are disposed on a stacked substrate obtained by stacking a plurality of semiconductor substrates.

In FIG. 3, the overall control unit 103 controls operation of the distance measurement unit 2 overall according to, for example, a program incorporated in advance. Furthermore, the overall control unit 103 can also execute control according to an external control signal supplied from outside. The clock generation unit 104 generates one or more clock signals used in the distance measurement unit 2 on the basis of a reference clock signal supplied from the outside.

Operation of the SPAD pixels 10 is controlled by the pixel control unit 102 according to an instruction from the overall control unit 103. For example, the pixel control unit 102 can control an SPAD pixel 10 alone or for each block including a plurality of SPAD pixels 10.

The pixel signals read from the respective SPAD pixels 10 are supplied to the distance measurement processing unit 101. The distance measurement processing unit 101 includes a conversion unit 110, a generation unit 111, and a signal processing unit 112.

The pixel signals read from the respective SPAD pixels 10 are supplied to the conversion unit 110. Here, the pixel signals are asynchronously read from the respective SPAD pixels 10 and supplied to the conversion unit 110. That is, the pixel signals are read and output from the respective SPAD pixels 10 according to timings at which the respective SPAD pixels 10 receive light.

The conversion unit 110 converts the pixel signals output from the respective SPAD pixels 10 into digital information. That is, the pixel signals output from the respective SPAD pixels 10 are output according to timings at which the SPAD pixels 10 corresponding to the pixel signals receive light. The conversion unit 110 converts the pixel signals output from the SPAD pixels 10 into time information indicating the timings. The generation unit 111 generates a histogram on the basis of the time information obtained by the conversion unit 110 converting the pixel signals. The signal processing unit 112 performs predetermined calculation processing on the basis of data of the histogram generated by the generation unit 111, and calculates, for example, distance information. For example, the signal processing unit 112 creates curve approximation of the histogram on the basis of the data of the histogram generated by the generation unit 111. The signal processing unit 112 can detect a peak of a curve approximated by the histogram and obtain a distance on the basis of the detected peak.

When performing the curve approximation of the histogram, the signal processing unit 112 can perform filter processing on the curve obtained by approximating the histogram. For example, the signal processing unit 112 can reduce noise components by performing low-pass filter processing on the curve obtained by approximating the histogram.

The distance information obtained by the signal processing unit 112 is supplied to the interface 106. The interface 106 outputs the distance information supplied from the signal processing unit 112 to the outside as output data. For example, a mobile industry processor interface (MIPI) can be applied as the interface 106.

Note that, in the above description, the distance information obtained by the signal processing unit 112 is output to the outside via the interface 106, but this is not limited to this example. That is, histogram data, which is data of the histogram generated by the generation unit 111, may be output from the interface 106 to the outside. The histogram data output from the interface 106 is supplied to, for example, an external information processing device and processed as appropriate.

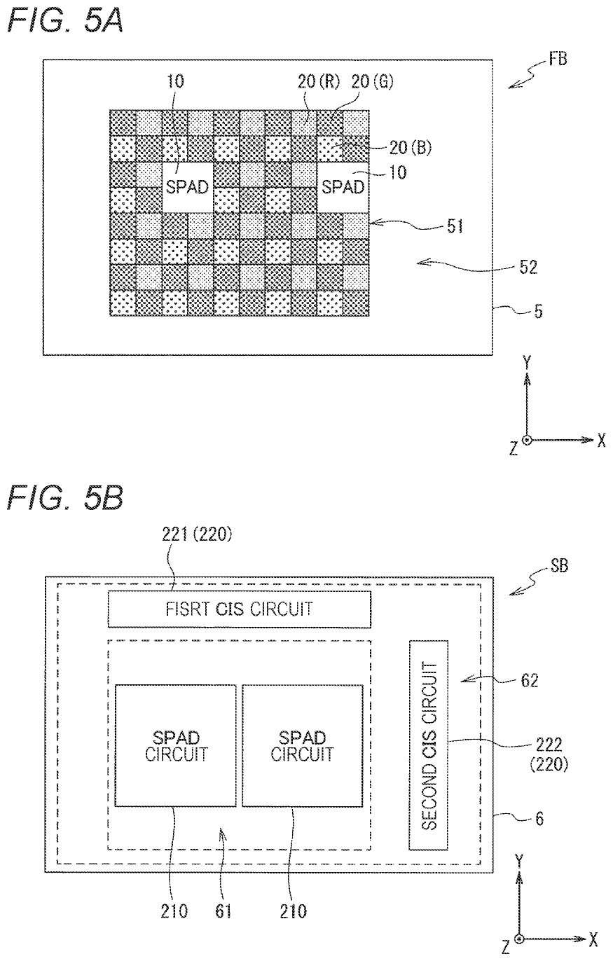

Note that at least a part of each function of the distance measurement processing unit 101 illustrated in FIG. 3 is executed by an SPAD circuit 210 to be described later. A relation between each function of the distance measurement processing unit 101 and the SPAD circuit 210 will be described later with reference to FIG. 5A.

(Positions of SPAD Circuit and CIS Circuit with Respect to Pixel Region)

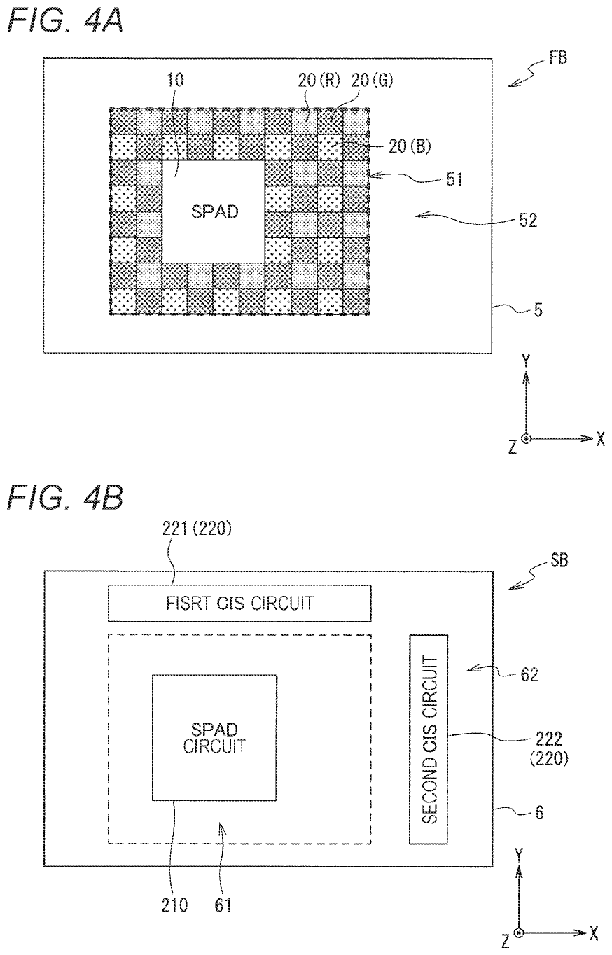

Next, positions of the SPAD circuit and CIS circuit with respect to a pixel region will be described. FIG. 4A is a plan view illustrating a first configuration example of a first substrate unit FB according to the first embodiment of the present disclosure. As illustrated in FIG. 4A, the first substrate unit FB includes a first semiconductor substrate 5, a pixel region 51 provided on the first semiconductor substrate 5, and a peripheral region 52 provided on the first semiconductor substrate 5. The peripheral region 52 is positioned around the pixel region 51. In the pixel region 51, the SPAD pixel 10 and the plurality of CIS pixels 20 are disposed in an array in a mixed manner. The SPAD pixel 10 and the CIS pixels 20 are not disposed in the peripheral region 52.

Note that, in FIG. 4A, the peripheral region 52 is illustrated to be relatively large with respect to the pixel region 51, but this is merely an example. In the first substrate unit FB, peripheral region 52 may be sufficiently smaller than the pixel region 51.

FIG. 4B is a plan view illustrating a first configuration example of a second substrate unit SB according to the first embodiment of the present disclosure. As illustrated in FIG. 4B, the second substrate unit SB includes a second semiconductor substrate 6, a first circuit region 61 provided on the second semiconductor substrate 6, and a second circuit region 62 provided on the second semiconductor substrate 6. The second circuit region 62 is positioned around the first circuit region 61. The SPAD circuit 210 connected to the SPAD pixel 10 is disposed in the first circuit region 61. A CIS circuit 220 (an example of a “visible-light pixel circuit” in the present disclosure) connected to the plurality of CIS pixels 20 is disposed in the second circuit region 62.

For example, the CIS circuit 220 includes a first CIS circuit 221 and a second CIS circuit 222. The first CIS circuit 221 includes the vertical drive circuit 13, horizontal drive circuit 15, and control circuit 17 illustrated in FIG. 2. The second CIS circuit 222 includes the column signal processing circuit 14 and output circuit 16 illustrated in FIG. 2.

In the sensor device 100 according to the first embodiment of the present disclosure, the second substrate unit SB is bonded to the first substrate unit FB. In this state, the pixel region 51 of the first substrate unit FB and the first circuit region 61 of the second substrate unit SB face each other in a direction in which the first semiconductor substrate 5 and the second semiconductor substrate 6 face each other (in the Z-axis direction, for example). In a case where a light-receiving surface of the pixel region 51 is on an upper side, the first circuit region 61 is positioned immediately below the pixel region 51. The SPAD circuit 210 disposed in the first circuit region 61 is positioned immediately below the pixel region 51.

Similarly, in a state where second substrate unit SB is bonded to first substrate unit FB, the peripheral region 52 in the first substrate unit FB and the second circuit region 62 in second substrate unit SB face each other in the Z-axis direction. In a case where the light-receiving surface of the pixel region 51 is on the upper side, the second circuit region 62 is positioned immediately below the peripheral region 52. The CIS circuit 220 disposed in the second circuit region 62 is positioned immediately below the peripheral region 52. The CIS circuit 220 is not positioned immediately below the pixel region 51.

Furthermore, the sensor device 100 according to the first embodiment of the present disclosure may include the plurality of SPAD pixels 10 in the pixel region 51 in the first semiconductor substrate 5. FIG. 5A is a plan view illustrating a second configuration example of the first substrate unit FB according to the first embodiment of the present disclosure. As illustrated in FIG. 5A, in the pixel region 51 according to the first semiconductor substrate 5, the plurality of SPAD pixels 10 and the plurality of CIS pixels 20 may be disposed in an array in a mixed manner. In this case, also, the SPAD pixels 10 and the CIS pixels 20 are not disposed in the peripheral region 52 in the first semiconductor substrate 5.

In the first configuration example illustrated in FIG. 4A, there has been described a case where a size (that is, a pixel area) of the SPAD pixel 10 in plan view is 16 times (four times longer in the X-axis direction and four times longer in the Y-axis direction) a pixel area of a CIS pixel 20, but this is merely an example. For example, as illustrated in FIG. 5A, the pixel area of an SPAD pixel 10 may be four times (twice longer in the X-axis direction and twice longer in the Y-axis direction) the pixel area of the CIS pixel 20.

FIG. 5B is a plan view illustrating a second configuration example of the second substrate unit SB according to the first embodiment of the present disclosure. As illustrated in FIG. 5B, a plurality of SPAD circuits 210 may be disposed in the first circuit region 61 in the second semiconductor substrate 6. For example, in the first circuit region 61 in the second semiconductor substrate 6, the plurality of SPAD circuits 210 is disposed corresponding to the plurality of SPAD pixels 10 illustrated in FIG. 5A. One SPAD circuit 210 corresponding to one SPAD pixel 10 is disposed immediately below the one SPAD pixel 10. The CIS circuit 220 is positioned immediately below the peripheral region 52 illustrated in FIG. 5A.

### (Configuration Example of SPAD Circuit)

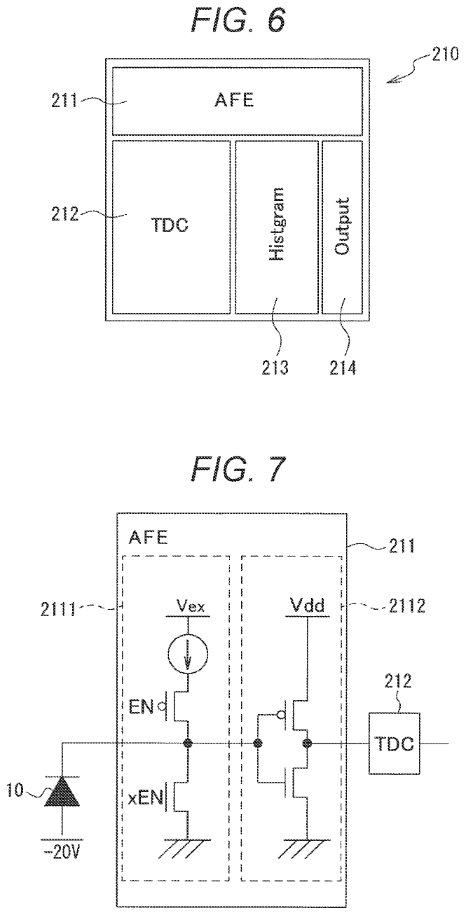

FIG. 6 is a diagram illustrating a configuration example of an SPAD circuit 210 positioned immediately below a pixel region 51. As illustrated in FIG. 6, the SPAD circuit 210 includes an analog front end (AFE) circuit 211, a time to digital converter (TDC) circuit 212, a Histgram circuit 213, and an Output unit 214. As a result, the SPAD circuit 210 executes at least a part of each function of the distance measurement processing unit 101.

For example, the AFE circuit 211 converts a pixel signal output from each SPAD pixel 10 into digital information as a part of functions of the conversion unit 110 in the distance measurement processing unit 101 illustrated in FIG. 3.

The TDC circuit 212 converts digital information output from the AFE circuit 211 into time information as another part of the functions of the conversion unit 110. As each function of the generation unit 111 and signal processing unit 112 of the distance measurement processing unit 101 illustrated in FIG. 3, the Histgram circuit 213 generates a histogram on the basis of the time information output from the TDC circuit 212, and performs predetermined calculation processing on the basis of data of the generated histogram to calculate distance information. The Output unit 214 outputs, to the outside, the calculated distance information as output data as a function of the interface 106.

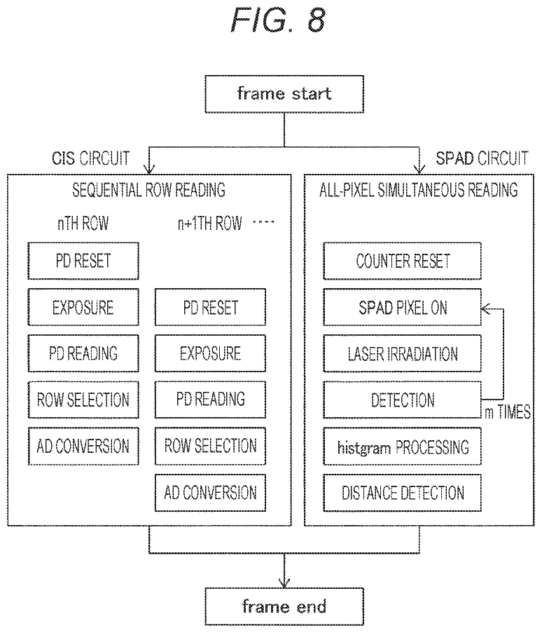

FIG. 7 is a diagram illustrating an SPAD pixel 10, a connection example of an AFE circuit 211 and a TDC circuit 212, and a configuration example of the AFE circuit 211. As illustrated in FIG. 7, the AFE circuit 211 includes a quench circuit 2111 and an inverter circuit 2112 connected to an output side of the quench circuit 2111. The SPAD pixel 10 is connected to an input side of the quench circuit 2111. The TDC circuit 212 is connected to an output side of the inverter circuit 2112.

### (Operation Example of Circuit)

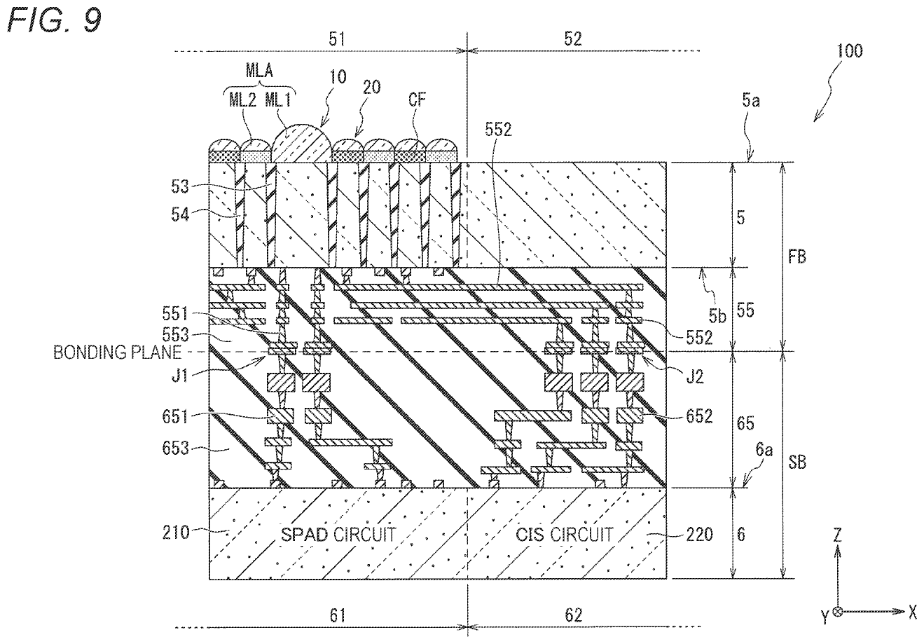

FIG. 8 is a flowchart illustrating each operation example of an SPAD circuit 210 and CIS circuit 220 in the sensor device 100. As illustrated in FIG. 8, while a signal for one screen is read (that is, a period from frame start to frame end), the CIS circuit 220 performs sequential row reading operation, and in parallel with this, the SPAD circuit 210 performs all-pixel simultaneous reading operation.

For example, while a signal for one screen is read, the CIS circuit 220 sequentially performs photo diode (PD) reset, exposure, PD reading, row selection, and analog to digital (AD) conversion, in order of an nth row (n is an integer of 1 or more), an (n+1)th row, and an (n+2)th row . . . . The CIS circuit 220 performs PD reset of the (n+1)th row at a timing of exposure of the nth row. Furthermore, while a signal for one screen is read, the SPAD circuit 210 performs counter reset, SPAD pixel (SPAD element) ON, laser irradiation, detection, histgram processing, and distance detection. Processing from the SPAD pixel ON to the detection is performed m times (m is an integer of 1 or more) as necessary.

### (Example of Cross-Sectional Structure)

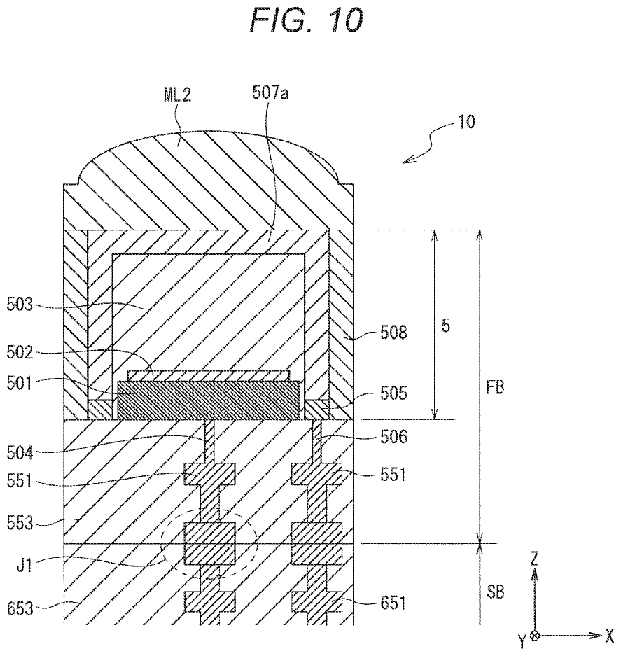

FIG. 9 is a cross-sectional view illustrating a configuration example of the sensor device 100 according to the first embodiment of the present disclosure. As illustrated in FIG. 9, the sensor device 100 includes the first substrate unit FB, the second substrate unit SB bonded to the first substrate unit FB, a color filter CF, and a microlens array MLA (an example of a “lens body” in the present disclosure). The sensor device 100 is, for example, a back-illuminated optical sensor, and a back surface 5a (in FIG. 9, an upper surface) of the first semiconductor substrate 5 is a light incident surface side. Therefore, the color filter CF and the microlens array MLA are disposed on the back surface 5a of the first semiconductor substrate 5.

The first substrate unit FB includes the first semiconductor substrate 5 and a first wiring layer 55 provided on a front surface 5b (a lower surface in FIG. 9; an example of “surface facing the second semiconductor substrate” in the present disclosure) of the first semiconductor substrate 5.

The first semiconductor substrate 5 is, for example, a silicon substrate formed by polishing a silicon wafer by chemical mechanical polishing (CMP). One or more SPAD pixels 10 and a plurality of CIS pixels 20 are provided on the first semiconductor substrate 5.

Color filter CF and microlens array MLA are stacked in this order on the back surface 5a of the first semiconductor substrate 5 via a translucent insulation film (not illustrated). Furthermore, a microlens array MLA includes a microlens ML1 disposed on an SPAD pixel 10 and a microlens ML2 disposed on a CIS pixel 20. End parts of microlenses ML1 and ML2 adjacent to each other are connected to each other, and end parts of one microlens ML2 and another microlens ML2 adjacent to each other are connected to each other, by which one microlens array MLA is constituted.

The color filter CF is disposed on the CIS pixel 20, but is not disposed on the SPAD pixel 10. The microlens ML1 is disposed on the back surface 5a of the first semiconductor substrate 5 via the translucent insulation film (not illustrated). As a result, light transmitted through the microlens array MLA enters the SPAD pixel 10 without passing through the color filter CF. The light transmitted through the microlens array MLA enters the CIS pixel 20 through the color filter CF.

As illustrated in FIG. 9, the first semiconductor substrate 5 is provided with a first element isolation unit 53 having a trench structure and a second element isolation unit 54 having a trench structure. The first element isolation unit 53 is positioned between the SPAD pixel 10 and the CIS pixel 20. The second element isolation unit 54 is positioned between one CIS pixel 20 and another CIS pixel 20 adjacent to each other among the plurality of CIS pixels 20. Each of the first element isolation unit 53 and the second element isolation unit 54 has a trench formed in a depth direction from the back surface 5a of the first semiconductor substrate 5, and a filling film embedded in the trench. The filling film is, for example, an insulation film such as a silicon oxide film (SiO₂ film) or a polysilicon film. The filling film may have a fixed charge film provided so as to be in contact with an inner surface of the trench. Note that the trench of the first element isolation unit 53 is an example of a “first trench” in the present disclosure, and the trench of the second element isolation unit 64 is an example of a “second trench” in the present disclosure.

The first wiring layer 55 includes a first wiring line 551 connected to the SPAD pixel 10, a second wiring line 552 connected to the plurality of CIS pixels 20, and a first interlayer insulation film 553 covering the first wiring line 551 and the second wiring line 552. The first wiring line 551 and the second wiring line 552 are, for example, multilayer wiring lines formed over a plurality of layers. The first interlayer insulation film 553 is, for example, a stacked film formed through a plurality of times of film formation processes. The first wiring line 551 and the second wiring line 552 include metal such as aluminum (Al) or copper (Cu). The first interlayer insulation film 553 includes an insulation film such as a SiO₂ film.

The second substrate unit SB includes the second semiconductor substrate 6 and a second wiring layer 65 provided on a front surface 6a (an upper surface in FIG. 9; an example of “surface facing the first semiconductor substrate” in the present disclosure) of the second semiconductor substrate 6.

The second semiconductor substrate 6 is, for example, a silicon substrate formed by polishing a silicon wafer by CMP. The SPAD circuit 210 is provided in the first circuit region 61 of the second semiconductor substrate 6. The CIS circuit 220 is provided in the second circuit region 62 of the second semiconductor substrate 6.

The second wiring layer 65 includes a third wiring line 651 connected to the SPAD circuit 210, a fourth wiring line 652 connected to the CIS circuit 220, and a second interlayer insulation film 653 covering the third wiring line 651 and the fourth wiring line 652. The third wiring line 651 and the fourth wiring line 652 are, for example, multilayer wiring lines formed over the plurality of layers. The second interlayer insulation film 653 is, for example, a stacked film formed through a plurality of times of film formation processes. The third wiring line 651 and the fourth wiring line 652 include metal such as Al or Cu. The second interlayer insulation film 653 includes an insulation film such as a SiO₂ film.

For example, the first interlayer insulation film 553 and the second interlayer insulation film 653 are bonded to each other. On a bonding plane between the first interlayer insulation film 553 and the second interlayer insulation film 653, the first wiring line 551 and the third wiring line 651 are bonded by Cu—Cu bonding, and the second wiring line 552 and the fourth wiring line 652 are bonded by Cu—Cu bonding. A first junction part JI where the first wiring line 551 and the third wiring line 651 are bonded by Cu—Cu bonding is positioned between the pixel region 51 in the first semiconductor substrate 5 and the first circuit region 61 in the second semiconductor substrate 6. A second junction part J2 where the second wiring line 552 and the fourth wiring line 652 are bonded by Cu—Cu bonding is positioned between the peripheral region 52 in the first semiconductor substrate 5 and the second circuit region 62 in the second semiconductor substrate 6.

### (Configuration Example of SPAD Pixel)

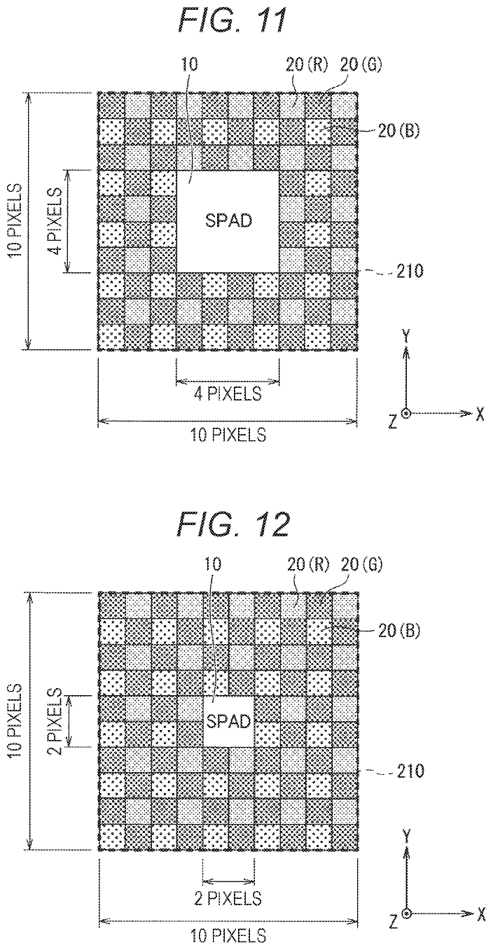

FIG. 10 is a cross-sectional view illustrating a configuration example of an SPAD pixel 10 according to the first embodiment of the present disclosure. FIG. 10 is a cross-sectional view illustrating a configuration example of the SPAD pixel 10 applicable to the distance measurement unit 2 according to the first embodiment of the present disclosure, the distance measurement unit 2 using the direct ToF system.

As illustrated in FIG. 10, in terms of conductivity types, the SPAD pixel 10 is provided with an N-type semiconductor region 501 and a P-type semiconductor region 502 in contact with the N-type semiconductor region 501. The N-type semiconductor region 501 and the P-type semiconductor region 502 are provided in a well layer 503.

The well layer 503 may be a semiconductor region a conductivity type of which is N-type or a semiconductor region a conductivity type of which is P-type. Furthermore, the well layer 503 preferably is a low-concentration N-type or P-type semiconductor region of 1E14 order or less, for example, whereby the well layer 503 may be easily depleted, and detection efficiency referred to as photon detection efficiency (PDE) may be improved.

The N-type semiconductor region 501 is an N-type semiconductor region including silicon (Si) for example, and having a high impurity concentration. The P-type semiconductor region 502 is a P-type semiconductor region having a high impurity concentration. The P-type semiconductor region 502 forms a pn junction at an interface with the N-type semiconductor region 501. The P-type semiconductor region 502 includes a multiplication region for performing avalanche multiplication on carriers generated by incidence of light to be detected. The P-type semiconductor region 502 is preferably depleted, whereby the PDE may be improved.

The N-type semiconductor region 501 functions as a cathode and is connected to the SPAD circuit 210 (refer to FIG. 9, for example) via a contact 504. An anode 505 for the cathode is in the same layer as the N-type semiconductor region 501, and is provided between the N-type semiconductor region 501 and an isolation region 508. The anode 505 is connected to the SPAD circuit 210 via a contact 506.

The isolation region 508 for isolating the SPAD pixels 10 from each other is formed, and a hole accumulation region 507a is provided between the isolation region 508 and the well layer 503. The hole accumulation region 507a is formed on an upper side of the anode 505 and is provided electrically connected to the anode 505. Furthermore, the hole accumulation region 507a is provided between the well layer 503 and the isolation region 508. Moreover, the hole accumulation region 507a is also provided on an upper part of the well layer 503 (a light incident surface side of the SPAD pixel 10).

The hole accumulation region 507a is formed on a portion where different materials are in contact. In the example illustrated in FIG. 10, the isolation region 508 includes, for example, a silicon oxide film including material different from a material of the well layer 503, and therefore the hole accumulation region 507a is provided in order to reduce dark current generated at an interface. Furthermore, the hole accumulation region 507a is also formed at an interface with the well layer 503 on a side where the microlens ML2 is formed.

That is, the hole accumulation region 507a is provided on a surface other than a lower surface of the well layer 503 (surface on which the N-type semiconductor region 501 is provided). Alternatively, the hole accumulation region 507a may be provided on a surface other than an upper surface and lower surface of the well layer 503. The hole accumulation region 507a can be formed as a P-type semiconductor region.

The isolation region 508 is formed between the SPAD pixels 10 and isolates the SPAD pixels 10 from each other. That is, the isolation region 508 is formed in such a manner that the multiplication region is formed in one-to-one correspondence with each SPAD pixel 10. The isolation region 508 is formed in a two-dimensional lattice shape so as to completely surround a periphery of each multiplication region (SPAD pixel 10).

The isolation region 508 illustrated in FIG. 10 is included in the first element isolation unit 53 having a trench structure illustrated in FIG. 9, for example. The isolation region 508 is provided penetrating from an upper surface side to lower surface side of the well layer 503 in a stacking direction. Note that, other than the configuration in which the isolation region 508 entirely penetrates from the upper surface side to the lower surface side, for example, there may be adopted a configuration in which only a portion of the isolation region 508 penetrates, and the isolation region 508 is inserted halfway through the substrate.

### EXAMPLES OF SIZES OF SPAD PIXEL AND SPAD CIRCUIT WITH RESPECT TO CIS PIXEL

### First Example

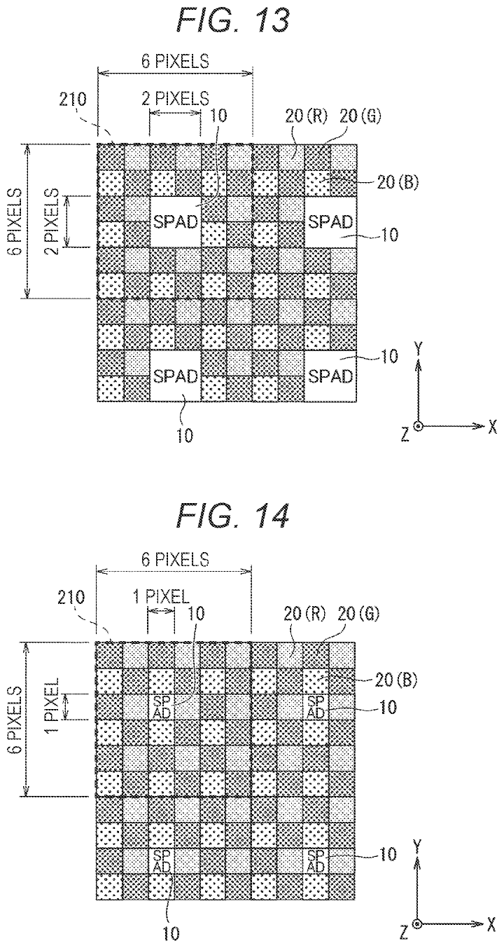

FIG. 11 is a plan view illustrating a size example (first example) of the SPAD pixel 10 and SPAD circuit 210 according to the first embodiment of the present disclosure. In the example illustrated in FIG. 11, similarly to the example illustrated in FIG. 4A, a pixel area of the SPAD pixel 10 is 16 times (length corresponding to four pixels in the X-axis direction and length corresponding to four pixels in the Y-axis direction) a pixel area of a CIS pixel 20.

Furthermore, although not illustrated, a disposition interval of the SPAD pixels 10 is 10 times a disposition interval of the CIS pixels 20. That is, a length of the disposition interval of the SPAD pixels 10 is a length corresponding to 10 CIS pixels 20.

As illustrated in FIG. 11, a size (that is, a circuit area) of the SPAD circuit 210 in plan view is 100 times (10 times longer in the X-axis direction and 10 times longer in the Y-axis direction) a pixel area of a CIS pixel 20. One SPAD circuit 210 is positioned immediately below one SPAD pixel 10.

That is, in the first example illustrated in FIG. 11, the plurality of SPAD pixels 10 is disposed at regular intervals each in the X-axis direction (an example of the “first direction” in the present disclosure) and in the Y-axis direction (an example of the “second direction” in the present disclosure) orthogonal to the X-axis direction. In a case where the disposition interval of the SPAD pixels 10 in the X-axis direction is a first pitch length and the disposition interval of the SPAD pixels 10 in the Y-axis direction is a second pitch length, the respective first pitch length and second pitch length are lengths corresponding to 10 CIS pixels 20. The circuit area of one SPAD circuit 210 corresponds to an area of 100 CIS pixels 20, and a value of the circuit area is the same as a product of the first pitch length and second pitch length described above. Note that the value of the circuit area of one SPAD circuit 210 may be smaller than a value of the product of the first pitch length and second pitch length described above.

### Second Example

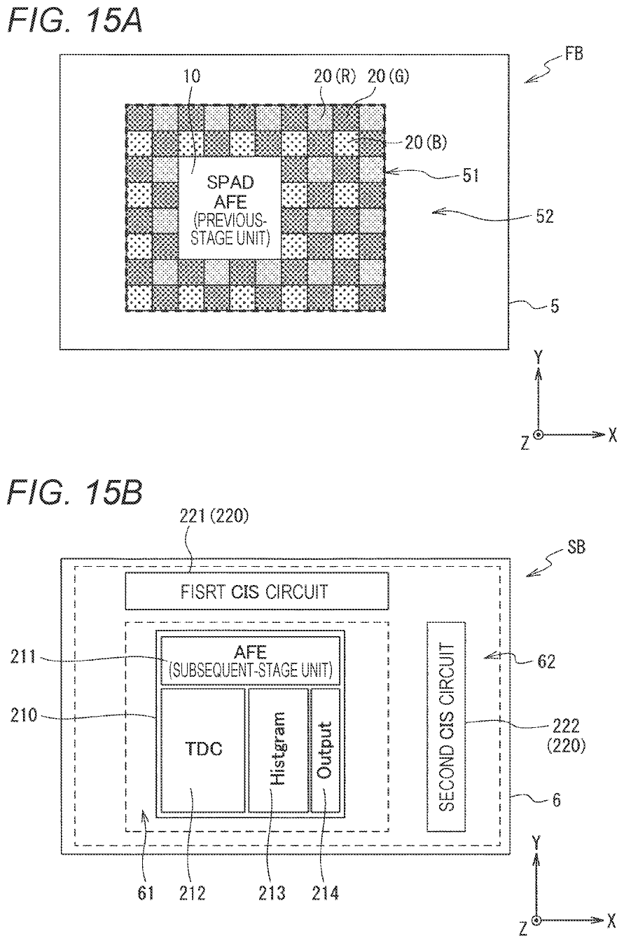

FIG. 12 is a plan view illustrating a size example (second example) of the SPAD pixel 10 and SPAD circuit 210 according to the first embodiment of the present disclosure. In the example illustrated in FIG. 12, similarly to the example illustrated in FIG. 5A, a pixel area of the SPAD pixel 10 is four times (length corresponding to two pixels in the X-axis direction and length corresponding to two pixels in the Y-axis direction) a pixel area of a CIS pixel 20. Furthermore, although not illustrated, a disposition interval of the SPAD pixels 10 is 10 times a disposition interval of the CIS pixels 20. That is, a length of the disposition interval of the SPAD pixels 10 is a length corresponding to 10 CIS pixels 20.

As illustrated in FIG. 12, a circuit area of the SPAD circuit 210 is 100 times (10 times longer in the X-axis direction and 10 times longer in the Y-axis direction) a pixel area of a CIS pixel 20. One SPAD circuit 210 is positioned immediately below one SPAD pixel 10.

That is, also in the second example illustrated in FIG. 12, the plurality of SPAD pixels 10 is disposed at regular intervals each in the X-axis direction and the Y-axis direction. In a case where the disposition interval of the SPAD pixels 10 in the X-axis direction is a first pitch length and the disposition interval of the SPAD pixels 10 in the Y-axis direction is a second pitch length, the respective first pitch length and second pitch length are lengths corresponding to 10 CIS pixels 20. The circuit area of one SPAD circuit 210 corresponds to an area of 100 CIS pixels 20, and a value of the circuit area is the same as a product of the first pitch length and second pitch length described above. Note that the value of the circuit area of one SPAD circuit 210 may be smaller than a value of the product of the first pitch length and second pitch length described above.

### Third Example

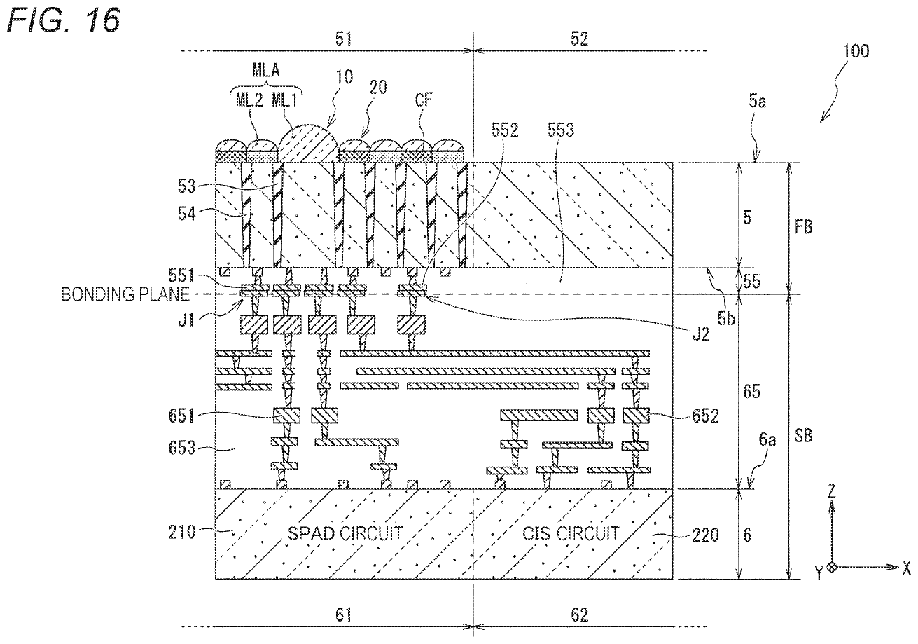

FIG. 13 is a plan view illustrating a size example (third example) of the SPAD pixels 10 and SPAD circuit 210 according to the first embodiment of the present disclosure. In the example illustrated in FIG. 13, similarly to the example illustrated in FIG. 5A, a pixel area of an SPAD pixel 10 is four times (length corresponding to two pixels in the X-axis direction and length corresponding to two pixels in the Y-axis direction) a pixel area of a CIS pixel 20. Furthermore, a disposition interval of the SPAD pixels 10 is six times a disposition interval of the CIS pixels 20. That is, a length of the disposition interval of the SPAD pixels 10 is a length corresponding to six CIS pixels 20.

As illustrated in FIG. 13, a circuit area of the SPAD circuit 210 is 36 times (six times longer in the X-axis direction and six times longer in the Y-axis direction) a pixel area of a CIS pixel 20. One SPAD circuit 210 is positioned immediately below one SPAD pixel 10.

That is, also in the third example illustrated in FIG. 13, the plurality of SPAD pixels 10 is disposed at regular intervals each in the X-axis direction and the Y-axis direction. In a case where the disposition interval of the SPAD pixels 10 in the X-axis direction is a first pitch length and the disposition interval of the SPAD pixels 10 in the Y-axis direction is a second pitch length, the respective first pitch length and second pitch length are lengths corresponding to six CIS pixels 20. The circuit area of one SPAD circuit 210 corresponds to an area of 36 CIS pixels 20, and a value of the circuit area is the same as a product of the first pitch length and second pitch length described above. Note that the value of the circuit area of one SPAD circuit 210 may be smaller than a value of the product of the first pitch length and second pitch length described above.

### Fourth Example

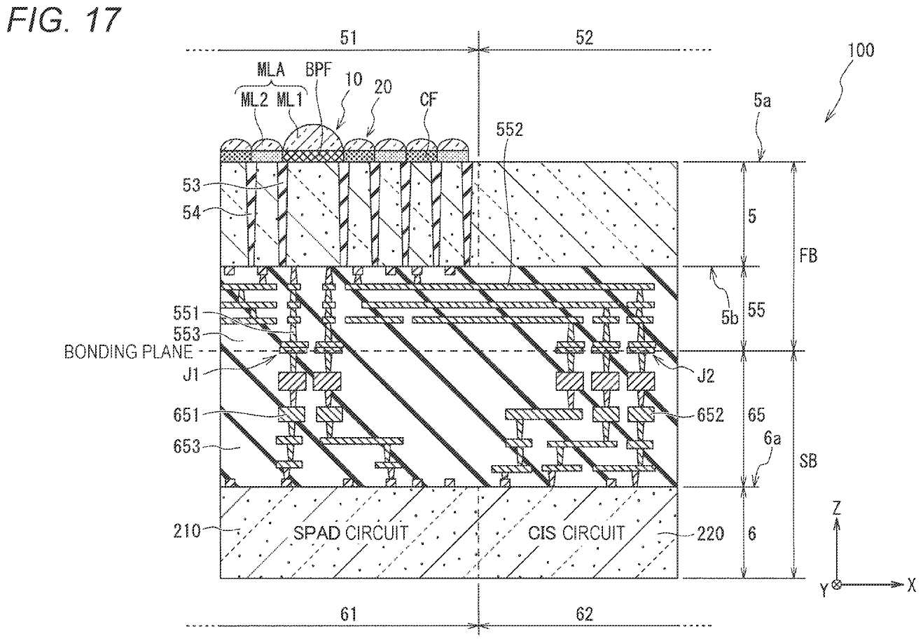

FIG. 14 is a plan view illustrating a size example (fourth example) of the SPAD pixels 10 and SPAD circuit 210 according to the first embodiment of the present disclosure. In the example illustrated in FIG. 14, a pixel area of an SPAD pixel 10 is 36 times (length corresponding to six pixels in the X-axis direction and length corresponding to six pixels in the Y-axis direction) a pixel area of a CIS pixel 20. Furthermore, a disposition interval of the SPAD pixels 10 is six times a disposition interval of the CIS pixels 20. That is, a length of the disposition interval of the SPAD pixels 10 is a length corresponding to six CIS pixels 20.

As illustrated in FIG. 14, a circuit area of the SPAD circuit 210 is 36 times (six times longer in the X-axis direction and six times longer in the Y-axis direction) a pixel area of a CIS pixel 20. One SPAD circuit 210 is positioned immediately below one SPAD pixel 10.

That is, also in the fourth example illustrated in FIG. 14, the plurality of SPAD pixels 10 is disposed at regular intervals each in the X-axis direction and the Y-axis direction. In a case where the disposition interval of the SPAD pixels 10 in the X-axis direction is a first pitch length and the disposition interval of the SPAD pixels 10 in the Y-axis direction is a second pitch length, the respective first pitch length and second pitch length are lengths corresponding to six CIS pixels 20. The circuit area of one SPAD circuit 210 corresponds to an area of 36 CIS pixels 20, and a value of the circuit area is the same as a product of the first pitch length and second pitch length described above. Note that the value of the circuit area of one SPAD circuit 210 may be smaller than a value of the product of the first pitch length and second pitch length described above.

### (Effects of First Embodiment)

As described above, the sensor device 100 according to the first embodiment of the present disclosure includes the first substrate unit FB and the second substrate unit SB bonded to the first substrate unit FB. The first substrate unit FB includes the first semiconductor substrate 5 and the pixel region 51 provided on the first semiconductor substrate 5 and in which an SPAD pixel 10 and a plurality of CIS pixels 20 are mixed in an array. The second substrate unit SB includes the second semiconductor substrate 6 facing the first semiconductor substrate 5, the SPAD circuit 210 provided on the second semiconductor substrate 6 and connected to the SPAD pixel 10, and the CIS circuit 220 provided on the second semiconductor substrate 6 and connected to the plurality of CIS pixels 20.

With this arrangement, the sensor device 100 can use the plurality of CIS pixels 20 as pixels for imaging (for picture image acquisition, for example) and an SPAD pixel 10 as a pixel for distance measurement (for distance image acquisition, for example). In the first semiconductor substrate 5, the SPAD pixel 10 and the plurality of CIS pixels 20 are disposed in an array in a mixed manner, and therefore the sensor device 100 can acquire a picture image and a distance image on the same optical axis.

Furthermore, in the first semiconductor substrate 5, if the SPAD pixel 10 is miniaturized, a free region is generated around the SPAD pixel 10 by an amount of the miniaturization. In the sensor device 100, the SPAD pixel 10 and the plurality of CIS pixels 20 are disposed in an array in a mixed manner, and therefore the CIS pixels 20 can be disposed in the free region generated by miniaturization of the SPAD pixel 10. As a result, the SPAD pixel 10 can be miniaturized without a size thereof being limited to a size of the SPAD circuit 210 positioned immediately below the SPAD pixel 10.

Furthermore, the SPAD circuit 210 is only required to perform distance image acquisition processing, and does not need to perform picture image acquisition processing. Therefore, as compared with a case where the SPAD pixel 10 performs both the picture image acquisition processing and the distance image acquisition processing, it is possible to reduce load from image processing by a circuit (the SPAD circuit 210, for example) disposed at a subsequent stage of the SPAD pixel 10. Because the load from the image processing can be reduced, power consumption can be reduced.

Furthermore, in the sensor device 100, the second semiconductor substrate 6 includes the first circuit region 61 of which position overlaps a position of the pixel region 51 in the first semiconductor substrate 5 in the Z-axis direction, and the second circuit region 62 positioned around the first circuit region 61 and of which position does not overlap the position of the pixel region 51 in the Z-axis direction. The SPAD circuit 210 is disposed in the first circuit region, and the CIS circuit 220 is disposed in the second circuit region.

With this arrangement, it is easy to densely dispose the SPAD circuit 210 immediately below the pixel region 51. As a result, it is easy to increase the number of SPAD pixels 10 disposed in the pixel region 51 and to reduce disposition interval of the SPAD pixels 10.

### (Modification 1)

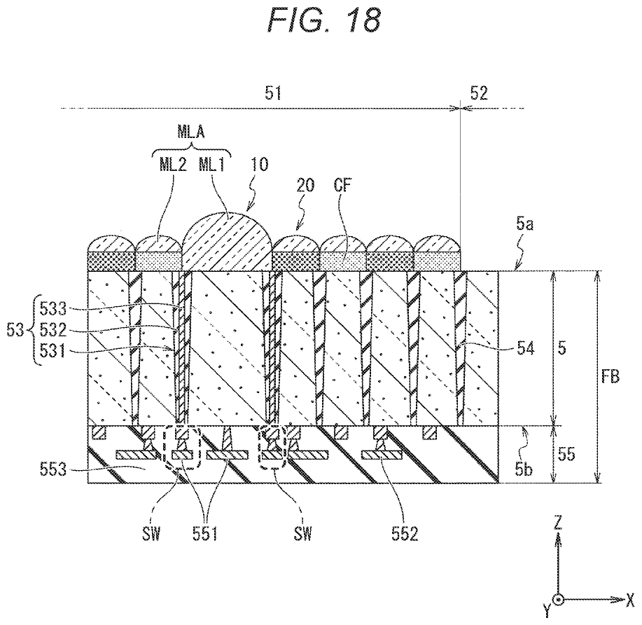

FIG. 15A is a plan view illustrating a configuration example (Modification 1) of the first substrate unit FB according to the first embodiment of the present disclosure. FIG. 15B is a plan view illustrating a configuration example (Modification 1) of the second substrate unit SB according to the first embodiment of the present disclosure. As illustrated in FIG. 15A, the SPAD pixel 10 according to the first substrate unit FB may include a previous-stage unit of AFE. Examples of the previous-stage unit of the AFE include the quench circuit 2111 illustrated in FIG. 7. In this case, as illustrated in FIG. 15B, the AFE circuit 211 in the second substrate unit SB includes a subsequent-stage unit of the AFE. Examples of the subsequent-stage unit of the AFE include the inverter circuit 2112 illustrated in FIG. 7. According to the modification illustrated in FIGS. 15A and 15B, the number of circuits included in the AFE circuit 211 can be reduced, and therefore there is a possibility that the circuit area of the SPAD circuit 210 can be reduced.

### (Modification 2)

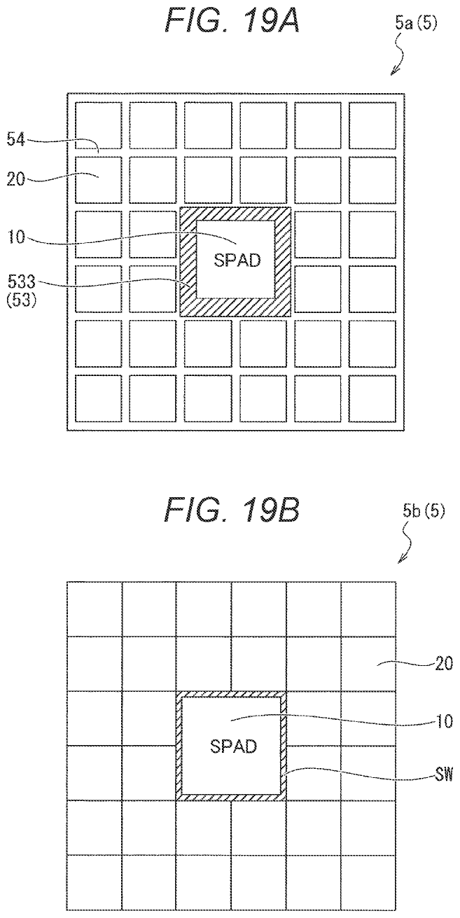

FIG. 16 is a cross-sectional view illustrating a configuration example (Modification 2) of the sensor device 100 according to the first embodiment of the present disclosure. As illustrated in FIG. 16, the first wiring line 551 and second wiring line 552 in the first wiring layer 55 in the first substrate unit FB may be not multilayer wiring lines formed over a plurality of layers but single-layer wiring lines. Each of the first junction part J1 where the first wiring line 551 and the third wiring line 651 are bonded by Cu—Cu bonding and the second junction part J2 where the second wiring line 552 and the fourth wiring line 652 are bonded by Cu—Cu bonding may be positioned between the pixel region 51 in the first semiconductor substrate 5 and the first circuit region 61 in the second semiconductor substrate 6. With such a configuration also, miniaturization of pixels in the sensor device 100 is possible.

### (Modification 3)

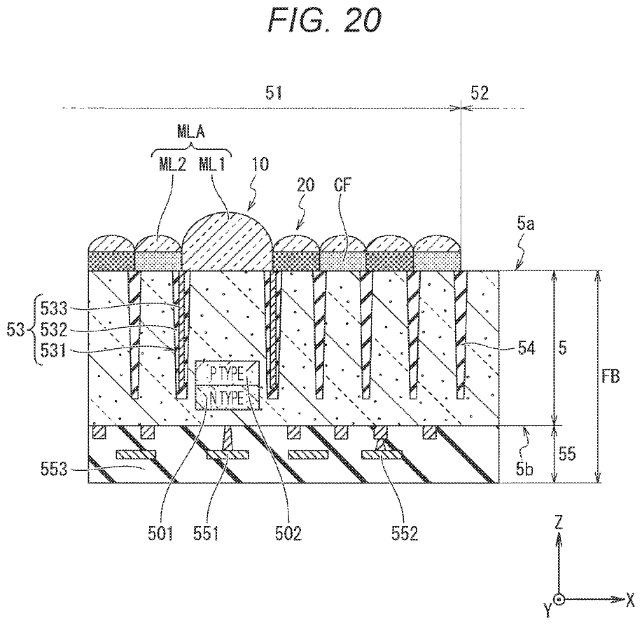

FIG. 17 is a cross-sectional view illustrating a configuration example (Modification 3) of the sensor device 100 according to the first embodiment of the present disclosure. As illustrated in FIG. 17, the sensor device 100 may include a bandpass filter BPF (an example of an “optical filter” in the present disclosure) between the SPAD pixel 10 and the microlens ML1. The bandpass filter BPF includes, for example, a function of transmitting infrared light (an example of “light having a preset wavelength” in the present disclosure) and blocking light other than the infrared light. With such a configuration, the SPAD pixel 10 can detect only infrared light, and therefore noise can be reduced.

### (Modification 4)

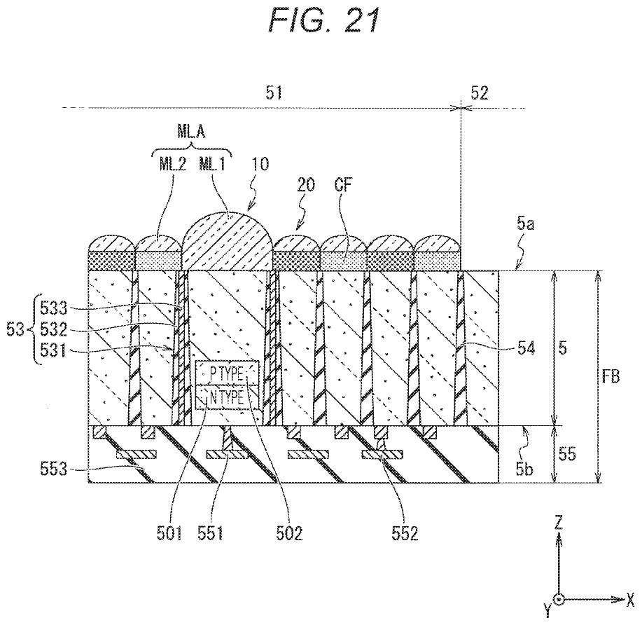

FIG. 18 is a cross-sectional view illustrating a configuration example (Modification 4) of the first substrate unit FB according to the first embodiment of the present disclosure. As illustrated in FIG. 18, in the first substrate unit FB, the first element isolation unit 53 having a trench structure surrounding a periphery of the SPAD pixel 10 may have a structure in which a light-shielding film is embedded. For example, the first element isolation unit 53 may include a trench 531 (an example of a “first trench” in the present disclosure) provided from the back surface (light-receiving surface) 5a of the first semiconductor substrate 5 toward the front surface 5b of the first semiconductor substrate 5, an insulation film 532 provided on an inner surface of the trench 531, and a light-shielding film 533 embedded in the trench 531 via the insulation film 532. The light-shielding film 533 may be, for example, a metal film including Al or the like, or a polysilicon film. In a case where the light-shielding film 533 is a polysilicon film, a light-shielding function can be obtained by, for example, a refractive index difference of a contact interface. The trench 531 penetrates the first semiconductor substrate 5.

The second element isolation unit 54 includes a trench 541 (an example of a “second trench” in the present disclosure) provided from the back surface 5a of the first semiconductor substrate 5 toward the front surface 5b of the first semiconductor substrate 5, and an insulation film 542 embedded in the trench 541. The trench 541 penetrates the first semiconductor substrate 5.

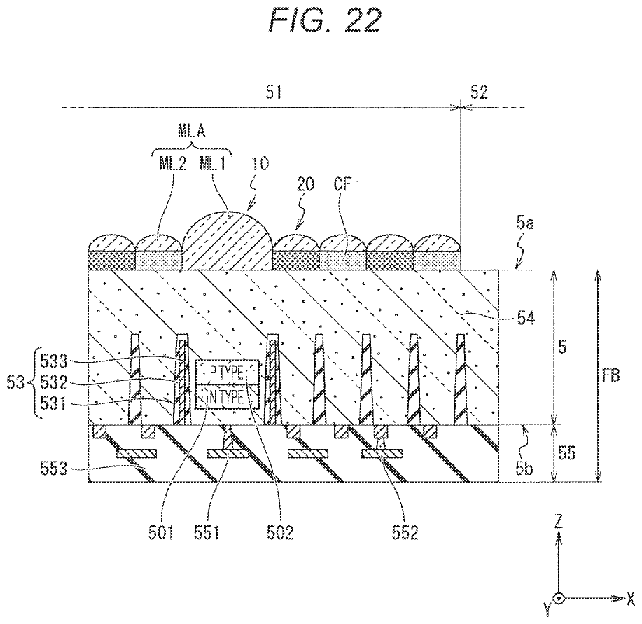

FIG. 19A is a plan view illustrating a configuration example (Modification 4) of the back surface 5a of the first semiconductor substrate 5. As illustrated in FIG. 19A, when viewed from the back surface 5a of the first semiconductor substrate 5, the SPAD pixel 10 is surrounded by the first element isolation unit 53 in which the light-shielding film 533 is embedded. Furthermore, a width of the trench 531 of the first element isolation unit 53 surrounding the SPAD pixel 10 is wider than a width of the trench 541 of the second element isolation unit 54 surrounding a CIS pixel 20.

With such a configuration, the first element isolation unit 53 can shield light between the SPAD pixel 10 and CIS pixel 20 in the first semiconductor substrate 5, and can reduce an amount of light incident from either the SPAD pixel 10 or the CIS pixel 20 to another, by which noise can be reduced.

FIG. 19B is a plan view illustrating a configuration example (Modification 4) of the front surface 5b of the first semiconductor substrate 5. As illustrated in FIGS. 18 and 19B, the first substrate unit FB may include a light-shielding wall SW (an example of a “light-shielding wall part” in the present disclosure) provided to surround a periphery of the SPAD pixel 10 on the front surface 5b of the first semiconductor substrate 5. The light-shielding wall SW may be configured by, for example, a part of the first wiring line 551, may be configured by a contact (the contact 506 illustrated in FIG. 10, for example) connecting the first wiring line 551 and the first element isolation unit 53, or may be configured by a combination thereof. Furthermore, the light-shielding wall SW may include a light shielding member provided separately from the first wiring line 551 and the contact described above. The light-shielding wall SW may be in contact with the light-shielding film 533 of the first element isolation unit 53.

With such a configuration, the light-shielding wall SW can shield light between the SPAD pixel 10 and the CIS pixel 20 in the first wiring layer 55. Because the light-shielding wall SW can reduce chances of light entering from either the SPAD pixel 10 or the CIS pixel 20 to another via the first wiring layer 55, noise can be reduced.

Note that FIG. 19B illustrates a case where the light-shielding wall SW is disposed in a line shape, but this is merely an example. light-shielding walls SW may be disposed in dots at narrow intervals.

### (Modification 5)

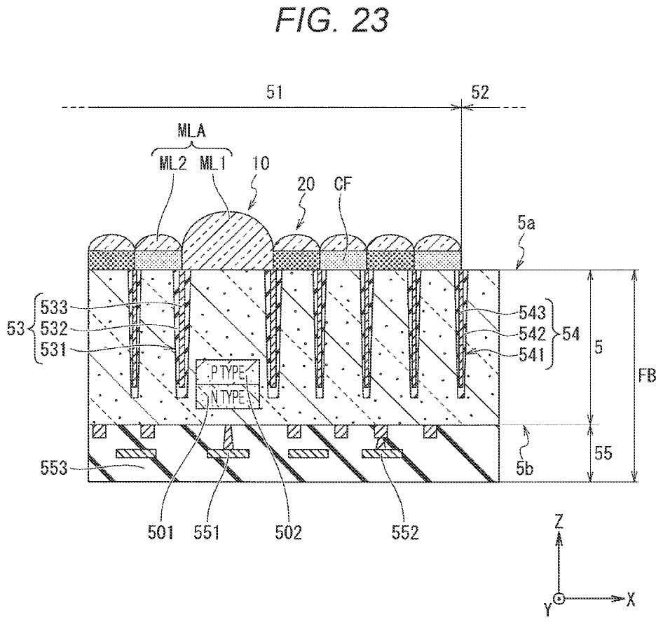

FIG. 20 is a cross-sectional view illustrating a configuration example (Modification 5) of the first substrate unit FB according to the first embodiment of the present disclosure. As illustrated in FIG. 20, in the first substrate unit FB, the first element isolation unit 53 may not penetrate the first semiconductor substrate 5. In Modification 4, the trench 531 of the first element isolation unit 53 is formed from the back surface 5a of the first semiconductor substrate 5 to a position halfway between the back surface 5a and the front surface 5b. A bottom surface of the trench 531 is positioned between the back surface 5a and front surface 5b of the first semiconductor substrate 5 and does not reach the front surface 5b.

In Modification 5, it is preferable that the bottom surface of the trench 531 be closer to the front surface 5b of the first semiconductor substrate 5 (that is, a side opposite to the light-receiving surface) than the multiplication region (that is, a PN-junction plane between the N-type semiconductor region 501 and the P-type semiconductor region 502) in the SPAD pixel 10 is. As a result, it becomes easy to shield the multiplication region in the SPAD pixel 10 from light from the surrounding CIS pixels 20, and noise can be reduced in the SPAD pixel 10.

### (Modification 6)

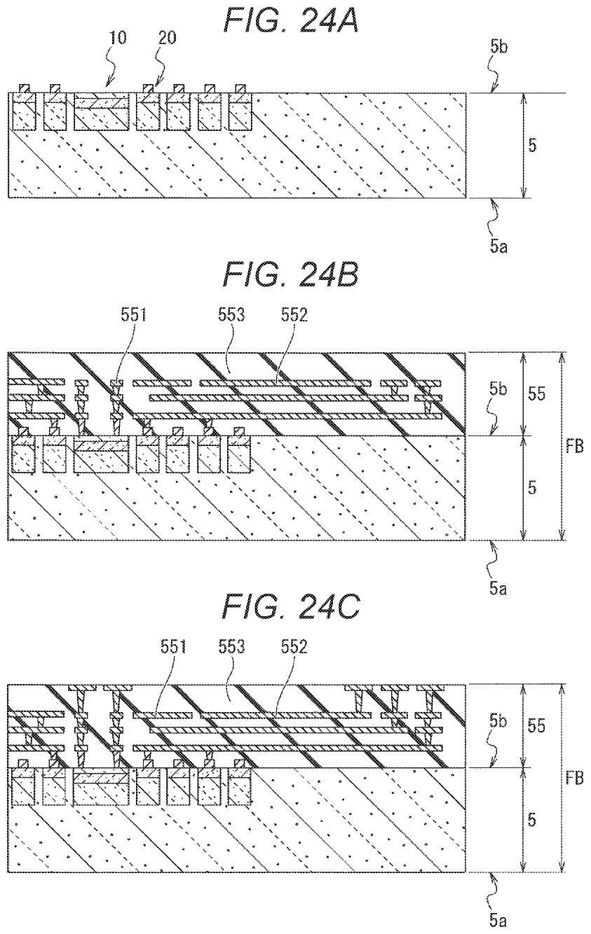

FIG. 21 is a cross-sectional view illustrating a configuration example (Modification 6) of the first substrate unit FB according to the first embodiment of the present disclosure. As illustrated in FIG. 21, in the first substrate unit FB, the trench 531 of the first element isolation unit 53 may be formed from the front surface 5b of the first semiconductor substrate 5 toward the back surface 5a of the first semiconductor substrate 5. In this case, side etching proceeds more on the front surface 5b of the first semiconductor substrate 5 than on the back surface 5a of the first semiconductor substrate 5, and therefore an opening diameter of the trench 531 is larger on the front surface 5b than on the back surface 5a. The trench 531 penetrates the first semiconductor substrate 5. With such a configuration also, miniaturization of pixels in the sensor device 100 is possible.

### (Modification 7)

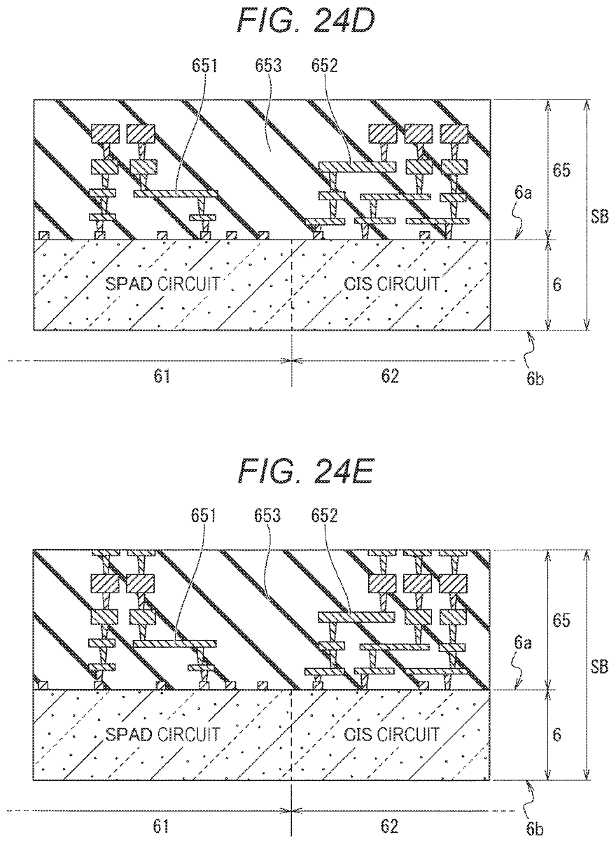

FIG. 22 is a cross-sectional view illustrating a configuration example (Modification 7) of the first substrate unit FB according to the first embodiment of the present disclosure. As illustrated in FIG. 22, also in a case where the trench 531 of the first element isolation unit 53 is formed from the front surface 5b of the first semiconductor substrate 5 toward the back surface 5a of the first semiconductor substrate 5, the trench 531 does not need to penetrate the first semiconductor substrate 5. The bottom surface of the trench 531 is positioned between the front surface 5b and back surface 5a of the first semiconductor substrate 5 and does not reach the back surface 5a. With such a configuration also, miniaturization of pixels in the sensor device 100 is possible.

Furthermore, in Modification 7, it is preferable that the bottom surface of the trench 531 be closer to the back surface 5a of the first semiconductor substrate 5 (that is, the light-receiving surface side) than the multiplication region (that is, the PN-junction plane between the N-type semiconductor region 501 and the P-type semiconductor region 502) in the SPAD pixel 10 is. As a result, it becomes easy to shield the multiplication region in the SPAD pixel 10 from light from the surrounding CIS pixels 20, and noise can be reduced in the SPAD pixel 10.

### (Modification 8)

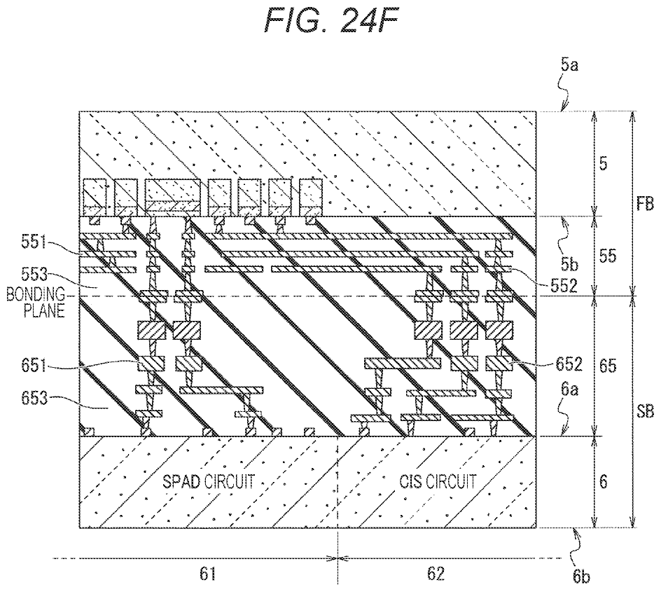

FIG. 23 is a cross-sectional view illustrating a configuration example (Modification 8) of the first substrate unit FB according to the first embodiment of the present disclosure. As illustrated in FIG. 23, the second element isolation unit 54 disposed between one CIS pixel 20 and another CIS pixel 20 adjacent to each other may have a structure in which a light-shielding film is embedded. For example, the second element isolation unit 54 may include a trench 541 (an example of a “second trench” in the present disclosure) provided from the back surface (light-receiving surface) Sa of the first semiconductor substrate 5 toward the front surface 5b of the first semiconductor substrate 5, an insulation film 542 provided on an inner surface of the trench 541, and a light-shielding film 543 embedded in the trench 541 via the insulation film 542. The light-shielding film 543 may be, for example, a metal film including Al or the like, or a polysilicon film. In a case where the light-shielding film 543 is a polysilicon film, a light-shielding function can be obtained by, for example, a refractive index difference of a contact interface.

### SECOND EMBODIMENT

Next, a method for manufacturing a sensor device 100 will be described as a second embodiment of the present disclosure. The sensor device 100 is manufactured by using various devices such as a film formation device (including a chemical vapor deposition (CVD) device, a sputtering device, and a thermal oxidation device), an exposure device, an etching device, and a CMP device. Hereinafter, these devices are collectively referred to as manufacturing devices.

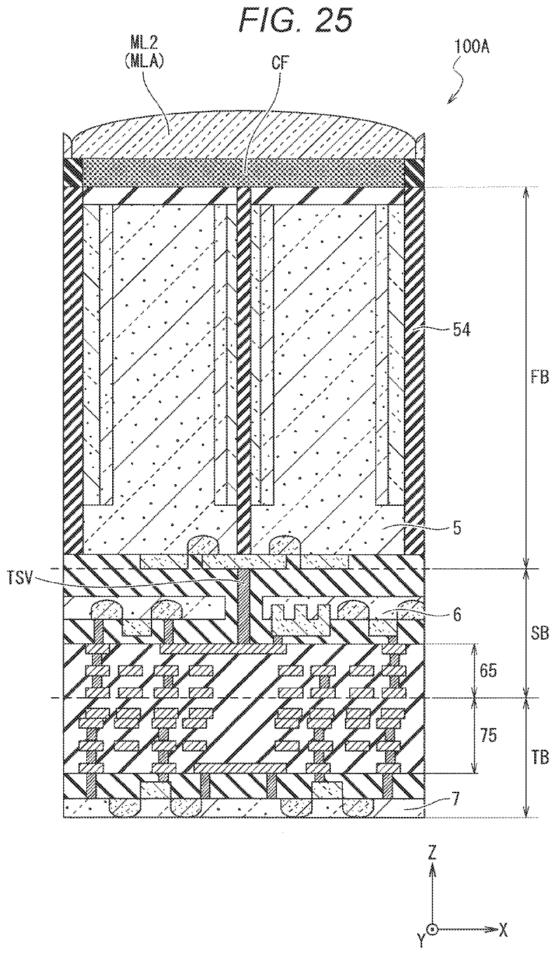

FIGS. 24A to 24F are cross-sectional views illustrating a method for manufacturing the sensor device 100 according to the second embodiment of the present disclosure in order of process. As illustrated in FIG. 24A, the manufacturing device forms an SPAD pixel 10 and a CIS pixel 20 on a front surface 5b of a first semiconductor substrate 5. Furthermore, on the front surface 5b of the first semiconductor substrate 5, the manufacturing device forms gate electrodes or the like for the respective SPAD pixel 10 and CIS pixel 20. Next, as illustrated in FIG. 24B, the manufacturing device forms a first wiring layer 55 on the front surface 5b of the first semiconductor substrate 5. Next, as illustrated in FIG. 24C, the manufacturing device forms a terminal for Cu—Cu connection to be an uppermost layer wiring of the first wiring layer 55.

Next, as illustrated in FIG. 24D, the manufacturing device forms, on a second semiconductor substrate 6, a logic circuit including an SPAD circuit 210 and a CIS circuit 220. Next, the manufacturing device forms a second wiring layer 65 on a front surface 6a of the second semiconductor substrate 6. Next, as illustrated in FIG. 24E, the manufacturing device forms a terminal for Cu—Cu connection to be an uppermost layer wiring of the second wiring layer 65.

Next, as illustrated in FIG. 24F, the manufacturing device causes the front surface 5b of the first semiconductor substrate 5 and the front surface 6a of the second semiconductor substrate 6 to face each other, and in this state, bonds the first substrate unit FB and the second substrate unit SB together. As a result, a first interlayer insulation film 553 and a second interlayer insulation film 653 are bonded, and the terminal positioned on an uppermost layer of the first wiring layer 55 and the terminal positioned on an uppermost layer of the second wiring layer 65 are bonded by Cu—Cu bonding.

Next, the manufacturing device performs CMP processing on a back surface 5a of the first semiconductor substrate 5 to thin the first semiconductor substrate 5 to a desired thickness. Thereafter, the manufacturing device attaches a color filter CF and a microlens array MLA on the back surface 5a of the first semiconductor substrate 5. Through the above processes, the sensor device 100 is completed.

### THIRD EMBODIMENT

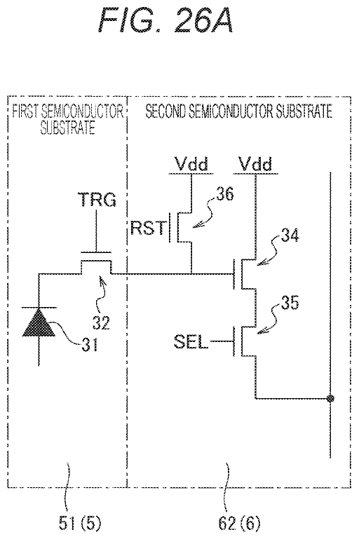

FIG. 25 is a cross-sectional view illustrating a configuration example of a sensor device 100A according to a third embodiment of the present disclosure. As illustrated in FIG. 25, a sensor device 100 according to the third embodiment further includes a third substrate unit TB disposed on an opposite side of a first substrate unit FB with a second substrate unit SB interposed therebetween. The third substrate unit TB includes a third semiconductor substrate 7. The third semiconductor substrate 7 is, for example, a silicon substrate.

A first semiconductor substrate 5 of the first substrate unit FB and a second semiconductor substrate 6 of the second substrate unit SB are connected via a through-silicon via TSV provided on the second semiconductor substrate 6. Furthermore, the second semiconductor substrate 6 and the third semiconductor substrate 7 are bonded by Cu—Cu bonding via a second wiring layer 65 provided on the second semiconductor substrate 6 and a third wiring layer 75 provided on the third semiconductor substrate 7.

In this example also, an SPAD pixel 10 (refer to FIG. 4A, for example) and a CIS pixel 20 (refer to FIG. 4A, for example) are provided on the first semiconductor substrate 5. An SPAD circuit 210 (refer to FIG. 4B) provided on the second semiconductor substrate 6 is disposed immediately below a pixel region 51 (refer to FIG. 4A, for example) in which the SPAD pixel 10 and the CIS pixel 20 are disposed. Furthermore, the CIS circuit 220 (refer to FIG. 4B, for example) is disposed on a portion of the second semiconductor substrate 6, the portion being positioned immediately below a peripheral region 52 of the first semiconductor substrate 5. The third semiconductor substrate 7 is provided with, for example, a logic circuit.

With such a configuration also, miniaturization of pixels in the sensor device 100 is possible, because the SPAD circuit 210 is disposed immediately below the pixel region 51 and the CIS circuit 220 is disposed immediately below the peripheral region 52.

Furthermore, not an entire SPAD circuit 210 but a part of the SPAD circuit 210 may be disposed on the second semiconductor substrate 6. In addition to the logic circuit, another part of the SPAD circuit 210 may be disposed on the third semiconductor substrate 7. In this case, the part of the SPAD circuit 210 may be a circuit to which a high voltage is applied (hereinafter, referred to as a high-voltage circuit), and the another part of the SPAD circuit 210 may be a circuit to which a low voltage is applied (hereinafter, referred to as a low-voltage circuit).

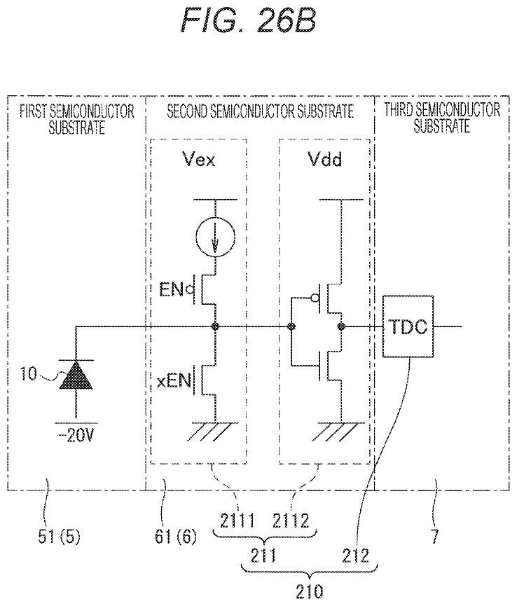

FIG. 26A is a circuit diagram illustrating an arrangement example of the CIS pixel 20 according to the third embodiment of the present disclosure. As illustrated in FIG. 26A, in the CIS pixel 20, a PN photodiode 31 and a transfer transistor 32 are disposed in the pixel region 51 of the first semiconductor substrate 5. In the CIS pixel 20, an amplification transistor 34, a selection transistor 35, and a reset transistor 36 are disposed in a second circuit region 62 of the second semiconductor substrate 6.

FIG. 26B is a circuit diagram illustrating an arrangement example of the SPAD pixel 10 and SPAD circuit 210 according to the third embodiment of the present disclosure. As illustrated in FIG. 26B, the SPAD pixel 10 is disposed in the pixel region 51 of the first semiconductor substrate 5. An AFE circuit 211 is disposed in a first circuit region 61 of the second semiconductor substrate 6. A TDC circuit 212 is disposed on the third semiconductor substrate 7. The AFE circuit 211 is the part of the SPAD circuit 210 and is a high-voltage circuit. The TDC circuit 212 is the another part of the SPAD circuit 210 and is a low-voltage circuit.

As a result, it is not necessary to form a low-voltage circuit on the second semiconductor substrate 6, and therefore, as compared with a case where a high-voltage circuit and a low-voltage circuit are formed on the second semiconductor substrate 6, a process of manufacturing the second semiconductor substrate 6 can be shortened, and costs for manufacturing the second semiconductor substrate 6 can be reduced. Furthermore, a low-voltage circuit has a narrower wiring width than a high-voltage circuit. Therefore, in the third semiconductor substrate 7, a low-voltage circuit and a logic circuit can be formed according to the same design rule. Because the low-voltage circuit and the logic circuit can be formed in parallel in the same manufacturing process, an increase in costs for manufacturing the third semiconductor substrate 7 can be suppressed. For the above reasons, there is a possibility that costs for manufacturing the sensor device 100A can be reduced.

### (Modification 1)

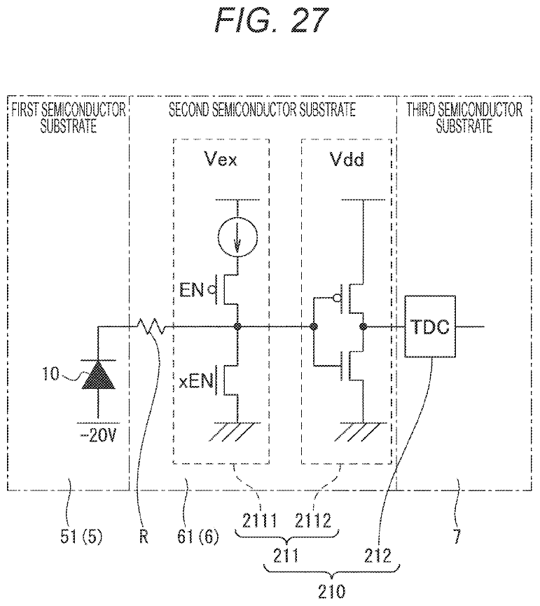

FIG. 27 is a circuit diagram illustrating an arrangement example (Modification 1) of the SPAD pixel 10 and SPAD circuit 210 according to the third embodiment of the present disclosure. As illustrated in FIG. 27, a resistive element R may be disposed between the SPAD pixel 10 and the SPAD circuit. The resistive element R includes, for example, polysilicon. The resistive element R is provided on the second semiconductor substrate 6, for example. The resistive element R serves as a quenching resistor to reduce chances of a sudden current change.

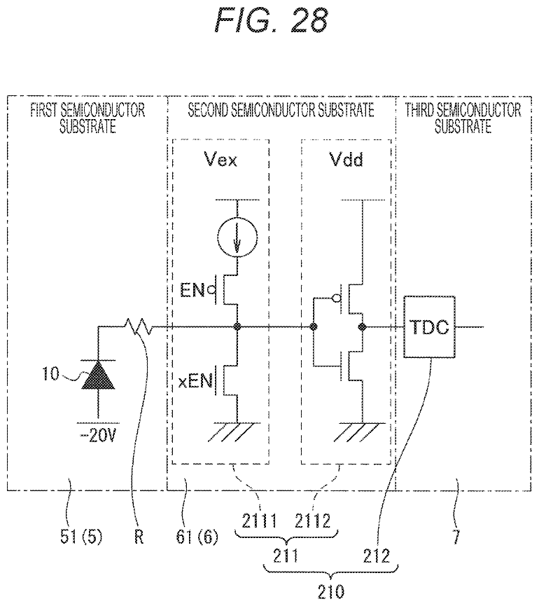

FIG. 28 is a circuit diagram illustrating an arrangement example (Modification 2) of the SPAD pixel 10 and SPAD circuit 210 according to the third embodiment of the present disclosure. As illustrated in FIG. 28, the resistive element R disposed between the SPAD pixel 10 and the SPAD circuit may be provided on the first semiconductor substrate 5.

### OTHER EMBODIMENT

As described above, the present disclosure has been described according to the embodiments and modified examples, but it should not be understood that the description and drawings forming a part of this disclosure limit the present disclosure. Various alternative embodiments, examples, and operation techniques will be apparent to those skilled in the art from this disclosure. It is a matter of course that the present technology includes various embodiments and the like not described herein. At least one of various omissions, substitutions, or changes of the components may be made without departing from the gist of the above-described embodiments and modified examples. Furthermore, the effects described herein are merely examples and are not limited, and other effects may be provided.

Note that the present disclosure can also have the following configurations.

(1) A sensor device including
a first substrate unit, and
a second substrate unit bonded to the first substrate unit,
in which the first substrate unit includes
a first semiconductor substrate, and
a pixel region provided on the first semiconductor substrate and in which an SPAD pixel and a plurality of visible-light pixels are mixed in an array, and
the second substrate unit includes
a second semiconductor substrate facing the first semiconductor substrate,
an SPAD circuit provided on the second semiconductor substrate and connected to the SPAD pixel, and
a visible-light pixel circuit provided on the second semiconductor substrate and connected to the plurality of visible-light pixels.

(2) The sensor device according to (1),
in which the second semiconductor substrate includes
a first circuit region of which position overlaps a position of the pixel region in a direction in which the first semiconductor substrate and the second semiconductor substrate face each other, and
a second circuit region positioned around the first circuit region and of which position does not overlap the position of the pixel region in the direction in which the first semiconductor substrate and the second semiconductor substrate face each other,
the SPAD circuit is disposed in the first circuit region, and
the visible-light pixel circuits are disposed in the second circuit region.

(3) The sensor device according to (2),
in which the first substrate unit includes
a first wiring layer provided on a surface of the first semiconductor substrate, the surface facing the second semiconductor substrate,
the second substrate unit includes
a second wiring layer provided on a surface of the second semiconductor substrate, the surface facing the first semiconductor substrate,
the first wiring layer includes
a first wiring line connected to the SPAD pixel, and
a second wiring line connected to the plurality of visible-light pixels,
the second wiring layer includes
a third wiring line connected to the SPAD circuit, and
a fourth wiring line connected to the visible-light pixel circuit,
the SPAD pixel and the SPAD circuit are connected to each other via the first wiring line and the third wiring line, and
the plurality of visible-light pixels and the visible-light pixel circuit are connected to each other via the second wiring line and the fourth wiring line.

(4) The sensor device according to (3),
in which the first wiring layer includes a first interlayer insulation film,
the second wiring layer includes a second interlayer insulation film bonded to the first interlayer insulation film, and
on a bonding plane between the first interlayer insulation film and the second interlayer insulation film, the first wiring line and the third wiring line are bonded by Cu—Cu bonding, and the second wiring line and the fourth wiring line are bonded by Cu—Cu bonding.

(5) The sensor device according to any one of (1) to (4),
in which the first semiconductor substrate includes
a first element isolation unit positioned between the SPAD pixel and the visible-light pixel, and
a second element isolation unit positioned between one visible-light pixel and another visible-light pixel adjacent to each other among the plurality of visible-light pixels,
the first element isolation unit includes a first trench provided on the first semiconductor substrate, and
the second element isolation unit includes a second trench provided on the first semiconductor substrate.

(6) The sensor device according to (5),
in which the first element isolation unit further includes a light-shielding film disposed in the first trench.

(7) The sensor device according to (5) or (6),
in which the first trench is wider than the second trench.

(8) The sensor device according to any one of (1) to (7),
in which the first substrate unit further includes a light-shielding wall part provided on a surface of the first semiconductor substrate, the surface facing the second semiconductor substrate, and surrounding the SPAD pixel.

(9) The sensor device according to any one of (1) to (8),
in which a plurality of the SPAD pixels is disposed in the pixel region, and a plurality of the SPAD circuits is disposed on the second semiconductor substrate, corresponding to the plurality of SPAD pixels.

(10) The sensor device according to (9),
in which the plurality of SPAD pixels is disposed at regular intervals in a first direction and a second direction orthogonal to the first direction, and
in a case where a disposition interval of the SPAD pixels in the first direction is a first pitch length and a disposition interval of the SPAD pixels in the second direction is a second pitch length,
an area of one the SPAD circuit is equal to or smaller than a product of the first pitch length and the second pitch length.

(11) The sensor device according to any one of (1) to (10), further including
a lens body disposed on an opposite side of the second semiconductor substrate with the first semiconductor substrate interposed therebetween, and
an optical filter disposed between the SPAD pixel and the lens body,
in which the optical filter transmits light having a preset wavelength, and blocks light other than the light having the preset wavelength.

(12) The sensor device according to any one of (1) to (11), further including a third substrate unit disposed on an opposite side of the first substrate unit with the second substrate unit interposed therebetween,
in which the third substrate unit includes a third semiconductor substrate,
a part of the SPAD circuit is disposed on the second semiconductor substrate, and
another part of the SPAD circuit is disposed on the third semiconductor substrate.

(13) The sensor device according to (12),
in which the part of the SPAD circuit is a circuit to which a high voltage is applied, and
the another part of the SPAD circuit is a circuit to which a low voltage is applied.

### REFERENCE SIGNS LIST

1 Imaging unit
2 Distance measurement unit
First semiconductor substrate
5a Back surface (light-receiving surface)
5b, 6a Front surface
6 Second semiconductor substrate
7 Third semiconductor substrate
10 SPAD pixel
13 Vertical drive circuit
14 Column signal processing circuit
15 Horizontal drive circuit
16 Output circuit
17 Control circuit
20 CIS pixel
22 Horizontal signal line
23 Vertical signal line
24 Data output signal line
30 Reading circuit
31 PN photodiode
32 Transfer transistor
33 Floating diffusion
34 Amplification transistor
35 Selection transistor
36 Reset transistor
51 Pixel region
52 Peripheral region
53 First element isolation unit
54 Second element isolation unit
55 First wiring layer
61 First circuit region
62 Second circuit region
65 Second wiring layer
75 Third wiring layer
100, 100A Sensor device
101 Distance measurement processing unit
102 Pixel control unit
103 Overall control unit
104 Clock generation unit
106 Interface (I/F)
106 Interface
110 Conversion unit
111 Generation unit
112 Signal processing unit
210 SPAD circuit
211 AFE circuit
212 TDC circuit
213 Histgram circuit
214 Output unit
220 CIS circuit
221 First CIS circuit
222 Second CIS circuit
501 N-type semiconductor region
502 P-type semiconductor region
503 Well layer
504 Contact
505 Anode
506 Contact
507a Hole accumulation region
508 Isolation region
531, 541 Trench
532, 542 Insulation film
533, 543 Light-shielding film
551 First wiring line
552 Second wiring line
553 First interlayer insulation film
651 Third wiring line
652 Fourth wiring line
653 Second interlayer insulation film
2111 quench circuit
2112 Inverter circuit
CF Color filter
FB First substrate unit
J1 First junction part
J2 Second junction part
ML1 Microlens
ML2 Microlens
MLA Microlens array
R Resistive element
RST Reset signal
SB Second substrate unit
SEL Selection signal
SW Light-shielding wall
TB Third substrate unit
TRG Transfer signal
TSV Through-silicon via
Vdd Drain power supply

What is claimed is:

1. A sensor device, comprising:
a first substrate unit; and
a second substrate unit bonded to the first substrate unit,
wherein the first substrate unit includes
a first semiconductor substrate, and
a pixel region provided on the first semiconductor substrate and in which an SPAD pixel and a plurality of visible-light pixels are mixed in an array, and
the second substrate unit includes
a second semiconductor substrate facing the first semiconductor substrate,
an SPAD circuit provided on the second semiconductor substrate and connected to the SPAD pixel, and
a visible-light pixel circuit provided on the second semiconductor substrate and connected to the plurality of visible-light pixels.

2. The sensor device according to claim 1,
wherein the second semiconductor substrate includes
a first circuit region of which position overlaps a position of the pixel region in a direction in which the first semiconductor substrate and the second semiconductor substrate face each other, and
a second circuit region positioned around the first circuit region and of which position does not overlap the position of the pixel region in the direction in which the first semiconductor substrate and the second semiconductor substrate face each other,
the SPAD circuit is disposed in the first circuit region, and
the visible-light pixel circuits are disposed in the second circuit region.

3. The sensor device according to claim 2,
wherein the first substrate unit includes
a first wiring layer provided on a surface of the first semiconductor substrate, the surface facing the second semiconductor substrate,
the second substrate unit includes
a second wiring layer provided on a surface of the second semiconductor substrate, the surface facing the first semiconductor substrate,
the first wiring layer includes
a first wiring line connected to the SPAD pixel, and
a second wiring line connected to the plurality of visible-light pixels,
the second wiring layer includes
a third wiring line connected to the SPAD circuit, and
a fourth wiring line connected to the visible-light pixel circuit,
the SPAD pixel and the SPAD circuit are connected to each other via the first wiring line and the third wiring line, and
the plurality of visible-light pixels and the visible-light pixel circuit are connected to each other via the second wiring line and the fourth wiring line.

4. The sensor device according to claim 3,
wherein the first wiring layer includes a first interlayer insulation film,
the second wiring layer includes a second interlayer insulation film bonded to the first interlayer insulation film, and
on a bonding plane between the first interlayer insulation film and the second interlayer insulation film, the first wiring line and the third wiring line are bonded by Cu—Cu bonding, and the second wiring line and the fourth wiring line are bonded by Cu—Cu bonding.

5. The sensor device according to claim 1,
wherein the first semiconductor substrate includes
a first element isolation unit positioned between the SPAD pixel and the visible-light pixel, and
a second element isolation unit positioned between one visible-light pixel and another visible-light pixel adjacent to each other among the plurality of visible-light pixels,
the first element isolation unit includes a first trench provided on the first semiconductor substrate, and
the second element isolation unit includes a second trench provided on the first semiconductor substrate.

6. The sensor device according to claim 5,
wherein the first element isolation unit further includes a light-shielding film disposed in the first trench.

7. The sensor device according to claim 5,
wherein the first trench is wider than the second trench.

8. The sensor device according to claim 1,
wherein the first substrate unit further includes a light-shielding wall part provided on a surface of the first semiconductor substrate, the surface facing the second semiconductor substrate, and surrounding the SPAD pixel.

9. The sensor device according to claim 1,
wherein a plurality of the SPAD pixels is disposed in the pixel region, and
a plurality of the SPAD circuits is disposed on the second semiconductor substrate, corresponding to the plurality of SPAD pixels.

10. The sensor device according to claim 9,
wherein the plurality of SPAD pixels is disposed at regular intervals in a first direction and a second direction orthogonal to the first direction, and
in a case where a disposition interval of the SPAD pixels in the first direction is a first pitch length and a disposition interval of the SPAD pixels in the second direction is a second pitch length,
an area of one the SPAD circuit is equal to or smaller than a product of the first pitch length and the second pitch length.

11. The sensor device according to claim 1, further comprising:
a lens body disposed on an opposite side of the second semiconductor substrate with the first semiconductor substrate interposed therebetween; and
an optical filter disposed between the SPAD pixel and the lens body,
wherein the optical filter transmits light having a preset wavelength, and blocks light other than the light having the preset wavelength.

12. The sensor device according to claim 1, further comprising a third substrate unit disposed on an opposite side of the first substrate unit with the second substrate unit interposed therebetween,
wherein the third substrate unit includes a third semiconductor substrate, a part of the SPAD circuit is disposed on the second semiconductor substrate, and another part of the SPAD circuit is disposed on the third semiconductor substrate.

13. The sensor device according to claim 12,
wherein the part of the SPAD circuit is a circuit to which a high voltage is applied, and
the another part of the SPAD circuit is a circuit to which a low voltage is applied.
